(19) United States
(12) Patent Application Publication
(10) Pub. No.: US 2024/0184213 A1
(43) Pub. Date: Jun. 6, 2024

(54) METHOD OF PATTERN SELECTION FOR A SEMICONDUCTOR MANUFACTURING RELATED PROCESS

(71) Applicant: ASML NETHERLANDS B.V., Veldhoven (NL)

(72) Inventor: Ayman HAMOUDA, Milpitas, CA (US)

(73) Assignee: ASML NETHERLANDS B.V., Veldhoven (NL)

(21) Appl. No.: 18/278,881

(22) PCT Filed: Feb. 28, 2022
(86) PCT No.: PCT/EP2022/054932

§ 371 Date: Aug. 25, 2023

Related U.S. Application Data
(60) Provisional application No. 63/299,430, filed on Jan. 14, 2022.
(60) Provisional application No. 63/158,092, filed on Mar. 8, 2021.

(51) Int. Cl. G03F 7/00; G06F 30/39; G06N 3/0464; G06N 20/00

(52) U.S. Cl. CPC G03F 7/705; G03F 7/70508; G06F 30/39; G06N 3/0464; G06N 20/00

(57) ABSTRACT

A method and apparatus for selecting patterns for training or calibrating models related to semiconductor manufacturing. The method includes obtaining a first set of patterns; representing each pattern of the first set of patterns in a representation domain, the representation domain corresponding to electromagnetic functions; and selecting a second set of patterns from the first set of patterns based on the representation domain.

### CROSS-REFERENCE TO RELATED APPLICATIONS

This application claims priority of U.S. application 63/158,092 which was filed on 8 Mar. 2021, and U.S. application 63/299,430 which was filed on 14 Jan. 2022, and which are incorporated herein in its entirety by reference.

### TECHNICAL FIELD

The description herein relates generally to improving lithography and related processes. More particularly, apparatuses, methods, and computer program products for selecting informative patterns for training models used in lithography or related process.

### BACKGROUND

A lithographic projection apparatus can be used, for example, in the manufacture of integrated circuits (ICs). In such a case, a patterning device (e.g., a mask) may contain or provide a pattern corresponding to an individual layer of the IC (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern on the patterning device. In general, a single substrate contains a plurality of adjacent target portions to which the pattern is transferred successively by the lithographic projection apparatus, one target portion at a time. In one type of lithographic projection apparatuses, the pattern on the entire patterning device is transferred onto one target portion in one go; such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the pattern on the patterning device are transferred to one target portion progressively. Since, in general, the lithographic projection apparatus will have a reduction ratio M (e.g., 4), the speed F at which the substrate is moved will be 1/M times that at which the projection beam scans the patterning device. More information with regard to lithographic devices can be found in, for example, U.S. Pat. No. 6,046,792, incorporated herein by reference.

Prior to transferring the pattern from the patterning device to the substrate, the substrate may undergo various procedures, such as priming, resist coating and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish off the individual layer of the device. If several layers are required in the device, then the whole procedure, or a variant thereof, is repeated for each layer. Eventually, a device will be present in each target portion on the substrate. These devices are then separated from one another by a technique such as dicing or sawing, whence the individual devices can be mounted on a carrier, connected to pins, etc.

Thus, manufacturing devices, such as semiconductor devices, typically involve processing a substrate (e.g., a semiconductor wafer) using a number of fabrication processes to form various features and multiple layers of the devices. Such layers and features are typically manufactured and processed using, e.g., deposition, lithography, etch, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc.

### SUMMARY

In an embodiment, there is provided a method for generating a training data set for computational lithography machine learning models. To obtain a model capable of accurate predictions for a wide range of future pattern instances, or model generality, adequate pattern coverage in the training process is critical. The training data is selected based on representing a set of patterns in a representative domain. For example, the set of patterns may be patterns within a target layout. The target layout can have hundreds of millions patterns, as such selection of a small number of, and collectively most informative, patterns for training purposes is desired. In an embodiment, performing selection of a subset of patterns is based on data points in the representation domain and further based on an information metric characterizing the amount of information in the subset of patterns. This selection process may enable selection of informative patterns without requiring an additional patterning related process models or machine learning models, for example an auto encoder-based pattern classification and selection process. As such, selection can be applied directly to the target layout that can also save a lot of computational resources and time.

According to an aspect of the present disclosure, patterns selection is based on maximizing the system entropy of the selected patterns as a whole. The total entropy is dependent on the selected patterns mutual information, e.g., distances among the patterns in the representation domain. In an embodiment, each pattern is represented as a cloud of pixel-embedded information in the representation domain. In an embodiment, each pattern is projected onto Hilbert Space for a linear pattern representation, e.g., with basis functions being Hermite Gaussian, Zernike, Bessel. The methods herein have several advantages. For example, the methods herein do not require training as a machine learning model such as an auto encoder. Handling pixel shift well. Good performance results according to RMS and LMC.

According to an aspect of the present disclosure, there is provided a method for selecting patterns based on mutual information between the patterns for training machine learning models related to semiconductor manufacturing. The method includes obtaining a set of patterns including a first pattern and a second pattern, each pattern of the set of patterns comprising one or more features; representing each pattern of the set of patterns as a group of data points in a representation domain, the first pattern represented as a first group of data points in the representation domain, and the second pattern represented as a second group of data points in the representation domain, each data point of the first group being indicative of information associated with features within a portion of the first pattern, and each data point of the second group is indicative of information associated with features within a portion of the second pattern; determining a set of distance values of a distance metric corresponding to the set of patterns, the set of distance values comprising a first distance value determined between the first group of data points and another group of data points, and the second distance value being determined between the second group of data points and the other group of data points, the distance metric being indicative of an amount of mutual information between a given pattern and the other pattern of the set of patterns; and selecting, based on the values of the distance metric breaching a distance threshold, a subset of patterns from the set of patterns.

In an embodiment, the representation domain is a linear representation domain or a Hilbert space domain.

According to another aspect, there is provided a method for selecting representative patterns for training machine learning models. The method includes obtaining a set of patterns; representing each pattern of the set of patterns as a group of data points in a representation domain; and selecting a subset of patterns from the set of patterns based on the groups of data points as a guide for mutual information between a given pattern and another pattern of the set of patterns. In an embodiment, the representation domain is a linear representation domain or a Hilbert space domain.

In an embodiment, the metric is indicative of non-homogeneity of each of the plurality of patterns. Hence, the metric can guide the selection of most informative patterns from, hundreds of millions of patterns from a target layout, for example.

In an embodiment, the selected sub-set of patterns can be provided as training data for training a model (e.g., OPC) associated with a patterning process.

While the foregoing paragraphs describe providing a linear representation of a pattern by projecting the pattern onto Hilbert Space, the embodiments of the present disclosure describe using basis functions that represent characteristics of a lithographic apparatus or process, e.g., characteristics of an illumination source of the lithographic apparatus, for projecting the pattern into a representation domain. For example, pattern information quality significantly depends on optical system diffraction (e.g., illumination source response to the pattern). In some embodiments, such characteristics of an optical system may be described using transmission cross coefficient (TCC), which may be determined using Hopkins' imaging model. The TCC may then be decomposed into a discrete set of coherent systems (e.g., sum of coherent systems (SOCS) TCCs), which represent electromagnetic field (EMF) transfer function of the individual coherent systems. A pattern may be projected onto Hilbert Space using the TCC functions as a basis function. For example, each pixel of a pattern may be projected onto a set (N) of TCCs to generate a N-dimension vector. The vector provides information about how a pattern-pixel is represented in the optical system. For example, the vector represents EMF excitation of a pixel based on a proximity of the pixel (e.g., how the proximity of the pixel is impacting an EMF excitation of the pixel). A pattern may be represented as a collection of pixels and accordingly, each pixel in the pattern may be represented as a vector, thereby generating a group of vectors or a cloud of vectors that is representative of the pattern. The clouds of vectors associated with different patterns may be analyzed for pattern similarity and a set of patterns having a metric that satisfies a criterion (e.g., one or more of a distance metric satisfying a distance threshold as described above, information entropy satisfying a specified criterion, etc.) may be selected as representative patterns (e.g., for calibrating or training models for determining characteristic of a lithographic apparatus or process, or for other purposes). In some embodiments, the above embodiments may also be modified to include resist characteristics (e.g., photoresist response to a pattern) in addition to or instead of the optical system characteristics in representing a pattern in a representation domain.

Such projection of the pattern onto a representation domain (e.g., using TCCs) is readily computable (e.g., once the configuration of the illumination source is known), is more accurate than conventional representations and therefore, provides an improved pattern similarity analysis for a better selection of representative patterns. Such projection advantageously does not require any training as in auto encoding techniques and thus faster pattern selection can be achieved.

According to an embodiment, there is provided a computer system comprising a non-transitory computer readable medium having instructions recorded thereon. The instructions, when executed by a computer, implement the method steps above.

### BRIEF DESCRIPTION OF THE DRAWINGS

The accompanying drawings, which are incorporated in and constitute a part of this specification, show certain aspects of the subject matter disclosed herein and, together with the description, help explain some of the principles associated with the disclosed embodiments. In the drawings,

FIG. 1 illustrates a block diagram of various subsystems of a lithographic projection apparatus, according to an embodiment.

FIG. 2 illustrates a flow chart of an exemplary method for simulating lithography in a lithographic projection apparatus, according to an embodiment.

FIG. 3 pictorially depicts transforming a pattern into pixel-embedded information in a representative domain having reduced dimensionality that dimensionality of the input pattern, the transforming being a convolution operation using a bounding box around the pixel of interest.

FIG. 4 is a flowchart of an exemplary method for selecting patterns from a target layout based on pattern related data points in a representative domain, according to an embodiment.

FIG. 5A is an example depicting transforming a pattern into a representative domain (e.g., coefficients of orthogonal basis functions), according to an embodiment.

FIG. 5B illustrates a group of data points in the representative domain, where a first group (light dots) representing a first pattern, and a second group (dark dots) representing a second pattern, according to an embodiment.

FIG. 6 illustrates an example selection of the patterns from a plurality of patterns of a portion of a design layout, according to an embodiment of the present disclosure.

FIG. 7 is a block diagram of an example computer system, according to an embodiment.

FIG. 8 is a schematic diagram of a lithographic projection apparatus, according to an embodiment.

FIG. 9 is a schematic diagram of another lithographic projection apparatus, according to an embodiment.

FIG. 10 is a detailed view of the lithographic projection apparatus, according to an embodiment.

FIG. 11 is a detailed view of the source collector module of the lithographic projection apparatus, according to an embodiment.

FIG. 12 is a flowchart of an exemplary method for selecting patterns from a target layout based on pattern representation in a source-based representative domain, according to an embodiment.

### DETAILED DESCRIPTION

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

In the present document, the terms “radiation” and “beam” may be used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The patterning device can comprise, or can form, one or more design layouts. The design layout can be generated utilizing CAD (computer-aided design) programs, this process often being referred to as EDA (electronic design automation). Most CAD programs follow a set of predetermined design rules in order to create functional design layouts/patterning devices. These rules are set by processing and design limitations. For example, design rules define the space tolerance between devices (such as gates, capacitors, etc.) or interconnect lines, so as to ensure that the devices or lines do not interact with one another in an undesirable way. One or more of the design rule limitations may be referred to as “critical dimension” (CD). A critical dimension of a device can be defined as the smallest width of a line or hole or the smallest space between two lines or two holes. Thus, the CD determines the overall size and density of the designed device. Of course, one of the goals in device fabrication is to faithfully reproduce the original design intent on the substrate (via the patterning device).

The term “mask” or “patterning device” as employed in this text may be broadly interpreted as referring to a generic patterning device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such patterning devices include a programmable mirror array and a programmable LCD array.

An example of a programmable mirror array can be a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic means.

An example of a programmable LCD array is given in U.S. Pat. No. 5,229,872, which is incorporated herein by reference.

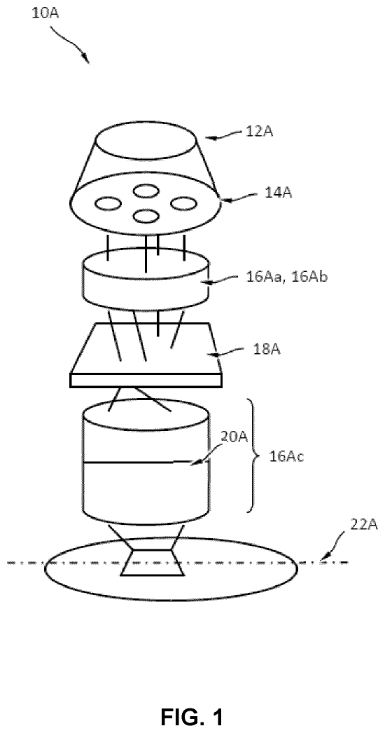

FIG. 1 illustrates a block diagram of various subsystems of a lithographic projection apparatus 10A, according to an embodiment. Major components are a radiation source 12A, which may be a deep-ultraviolet excimer laser source or other type of source including an extreme ultra violet (EUV) source (as discussed above, the lithographic projection apparatus itself need not have the radiation source), illumination optics which, e.g., define the partial coherence (denoted as sigma) and which may include optics 14A, 16Aa and 16Ab that shape radiation from the source 12A; a patterning device 18A; and transmission optics 16Ac that project an image of the patterning device pattern onto a substrate plane 22A. An adjustable filter or aperture 20A at the pupil plane of the projection optics may restrict the range of beam angles that impinge on the substrate plane 22A, where the largest possible angle defines the numerical aperture of the projection optics NA=n sin(Θmax), wherein n is the refractive index of the media between the substrate and the last element of the projection optics, and Θmax is the largest angle of the beam exiting from the projection optics that can still impinge on the substrate plane 22A.

In a lithographic projection apparatus, a source provides illumination (i.e. radiation) to a patterning device and projection optics direct and shape the illumination, via the patterning device, onto a substrate. The projection optics may include at least some of the components 14A, 16Aa, 16Ab and 16Ac. An aerial image (AI) is the radiation intensity distribution at substrate level. A resist model can be used to calculate the resist image from the aerial image, an example of which can be found in U.S. Patent Application Publication No. US 2009-0157630, the disclosure of which is hereby incorporated by reference in its entirety. The resist model is related only to properties of the resist layer (e.g., effects of chemical processes which occur during exposure, post-exposure bake (PEB) and development). Optical properties of the lithographic projection apparatus (e.g., properties of the illumination, the patterning device and the projection optics) dictate the aerial image and can be defined in an optical model. Since the patterning device used in the lithographic projection apparatus can be changed, it is desirable to separate the optical properties of the patterning device from the optical properties of the rest of the lithographic projection apparatus including at least the source and the projection optics. Details of techniques and models used to transform a design layout into various lithographic images (e.g., an aerial image, a resist image, etc.), apply OPC using those techniques and models and evaluate performance (e.g., in terms of process window) are described in U.S. Patent Application Publication Nos. US 2008-0301620, 2007-0050749, 2007-0031745, 2008-0309897, 2010-0162197, and 2010-0180251, the disclosure of each which is hereby incorporated by reference in its entirety.

According to an embodiment of the present disclosure, one or more images may be generated with various types of signals corresponding to pixel values (e.g., intensity values) of each pixel. Depending on the relative values of the pixel within the image, the signal may be referred as, for example, a weak signal or a strong signal, as may be understood by a person of ordinary skill in the art. The term “strong” and “weak” are relative terms based on intensity values of pixels within an image and specific values of intensity may not limit scope of the present disclosure. In an embodiment, the strong and weak signal may be identified based on a selected threshold value. In an embodiment, the threshold value may be fixed (e.g., a midpoint of a highest intensity and a lowest intensity of pixel within the image). In an embodiment, a strong signal may refer to a signal with values greater than or equal to an average signal value across the image and a weak signal may refer to signal with values less than the average signal value. In an embodiment, the relative intensity value may be based on percentage. For example, the weak signal may be a signal having intensity less than 50% of the highest intensity of the pixel (e.g., pixels corresponding to target pattern may be considered pixels with highest intensity) within the image. Furthermore, each pixel within an image may considered as a variable. According to the present embodiment, derivatives or partial derivative may be determined with respect to each pixel within the image and the values of each pixel may be determined or modified according to a cost function based evaluation and/or gradient based computation of the cost function. For example, a CTM image may include pixels, where each pixel is a variable that can take any real value.

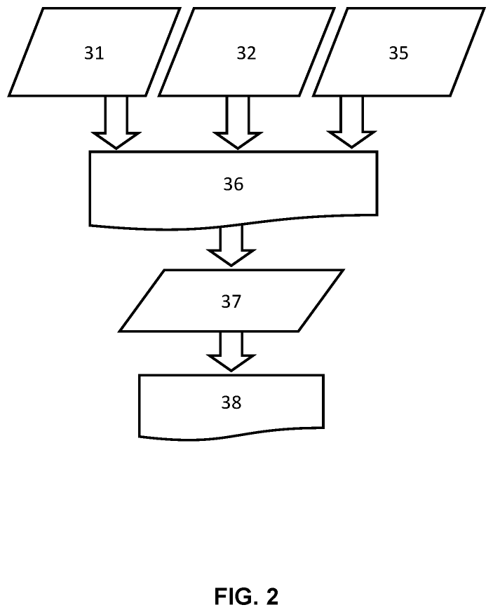

FIG. 2 illustrates an exemplary flow chart for simulating lithography in a lithographic projection apparatus, according to an embodiment. Source model 31 represents optical characteristics (including radiation intensity distribution and/or phase distribution) of the source. Projection optics model 32 represents optical characteristics (including changes to the radiation intensity distribution and/or the phase distribution caused by the projection optics) of the projection optics. Design layout model 35 represents optical characteristics of a design layout (including changes to the radiation intensity distribution and/or the phase distribution caused by design layout 33), which is the representation of an arrangement of features on or formed by a patterning device. Aerial image 36 can be simulated from design layout model 35, projection optics model 32, and design layout model 35. Resist image 38 can be simulated from aerial image 36 using resist model 37. Simulation of lithography can, for example, predict contours and CDs in the resist image.

More specifically, it is noted that source model 31 can represent the optical characteristics of the source that include, but not limited to, numerical aperture settings, illumination sigma (a) settings as well as any particular illumination shape (e.g. off-axis radiation sources such as annular, quadrupole, dipole, etc.). Projection optics model 32 can represent the optical characteristics of the projection optics, including aberration, distortion, one or more refractive indexes, one or more physical sizes, one or more physical dimensions, etc. Design layout model 35 can represent one or more physical properties of a physical patterning device, as described, for example, in U.S. Pat. No. 7,587,704, which is incorporated by reference in its entirety. The objective of the simulation is to accurately predict, for example, edge placement, aerial image intensity slope and/or CD, which can then be compared against an intended design. The intended design is generally defined as a pre-OPC design layout which can be provided in a standardized digital file format such as GDSII or OASIS or other file format.

From this design layout, one or more portions may be identified, which are referred to as “clips”. In an embodiment, a set of clips is extracted, which represents the complicated patterns in the design layout (typically about 50 to 1000 clips, although any number of clips may be used). These patterns or clips represent small portions (i.e. circuits, cells or patterns) of the design and more specifically, the clips typically represent small portions for which particular attention and/or verification is needed. In other words, clips may be the portions of the design layout, or may be similar or have a similar behavior of portions of the design layout, where one or more critical features are identified either by experience (including clips provided by a customer), by trial and error, or by running a full-chip simulation. Clips may contain one or more test patterns or gauge patterns.

An initial larger set of clips may be provided a priori by a customer based on one or more known critical feature areas in a design layout which require particular image optimization. Alternatively, in another embodiment, an initial larger set of clips may be extracted from the entire design layout by using some kind of automated (such as machine vision) or manual algorithm that identifies the one or more critical feature areas.

In a lithographic projection apparatus, as an example, a cost function may be expressed as

CF(z₁,z₂, . . . ,z_{N})=Σₚ₌₁^{p}wₚfₚ²(z₁,z₂, . . . ,z_{N}) (Eq. 1)

where (z₁, z₂, . . . , z_{N}) are N design variables or values thereof. fₚ(z₁, z₂, . . . , z_{N}) can be a function of the design variables (z₁, z₂, . . . , z_{N}) such as a difference between an actual value and an intended value of a characteristic for a set of values of the design variables of (z₁, z₂, . . . , z_{N}). wₚ is a weight constant associated with fₚ(z₁, z₂, . . . , z_{N}). For example, the characteristic may be a position of an edge of a pattern, measured at a given point on the edge. Different fₚ(z₁, z₂, . . . , z_{N}) may have different weight wₚ. For example, if a particular edge has a narrow range of permitted positions, the weight wₚ for the fₚ(z₁, z₂, . . . , z_{N}) representing the difference between the actual position and the intended position of the edge may be given a higher value. fₚ(z₁, z₂, . . . , z_{N}) can also be a function of an interlayer characteristic, which is in turn a function of the design variables (z₁, z₂, . . . , z_{N}). Of course, CF(z₁, z₂, . . . , z_{N}) is not limited to the form in Eq. 1. CF(z₁, z₂, . . . , z_{N}) can be in any other suitable form.

The cost function may represent any one or more suitable characteristics of the lithographic projection apparatus, lithographic process or the substrate, for instance, focus, CD, image shift, image distortion, image rotation, stochastic variation, throughput, local CD variation, process window, an interlayer characteristic, or a combination thereof. In one embodiment, the design variables (z₁, z₂, . . . , z_{N}) comprise one or more selected from dose, global bias of the patterning device, and/or shape of illumination. Since it is the resist image that often dictates the pattern on a substrate, the cost function may include a function that represents one or more characteristics of the resist image. For example, fₚ(z₁, z₂, . . . , z_{N}) can be simply a distance between a point in the resist image to an intended position of that point (i.e., edge placement error EPEₚ(z₁, z₂, . . . , z_{N}). The design variables can include any adjustable parameter such as an adjustable parameter of the source, the patterning device, the projection optics, dose, focus, etc.

The lithographic apparatus may include components collectively called a “wavefront manipulator” that can be used to adjust the shape of a wavefront and intensity distribution and/or phase shift of a radiation beam. In an embodiment, the lithographic apparatus can adjust a wavefront and intensity distribution at any location along an optical path of the lithographic projection apparatus, such as before the patterning device, near a pupil plane, near an image plane, and/or near a focal plane. The wavefront manipulator can be used to correct or compensate for certain distortions of the wavefront and intensity distribution and/or phase shift caused by, for example, the source, the patterning device, temperature variation in the lithographic projection apparatus, thermal expansion of components of the lithographic projection apparatus, etc. Adjusting the wavefront and intensity distribution and/or phase shift can change values of the characteristics represented by the cost function. Such changes can be simulated from a model or actually measured. The design variables can include parameters of the wavefront manipulator.

The design variables may have constraints, which can be expressed as (z₁, z₂, . . . , z_{N})ϵZ, where Z is a set of possible values of the design variables. One possible constraint on the design variables may be imposed by a desired throughput of the lithographic projection apparatus. Without such a constraint imposed by the desired throughput, the optimization may yield a set of values of the design variables that are unrealistic. For example, if the dose is a design variable, without such a constraint, the optimization may yield a dose value that makes the throughput economically impossible. However, the usefulness of constraints should not be interpreted as a necessity. For example, the throughput may be affected by the pupil fill ratio. For some illumination designs, a low pupil fill ratio may discard radiation, leading to lower throughput. Throughput may also be affected by the resist chemistry. Slower resist (e.g., a resist that requires higher amount of radiation to be properly exposed) leads to lower throughput.

As used herein, the term “patterning process” generally means a process that creates an etched substrate by the application of specified patterns of light as part of a lithography process. However, “patterning process” can also include plasma etching, as many of the features described herein can provide benefits to forming printed patterns using plasma processing.

As used herein, the term “target pattern” means an idealized pattern that is to be etched on a substrate. The term “target layout” refers to a design layout comprising one or more target patterns.

As used herein, the term “printed pattern” or “patterned substrate” means the physical pattern on a substrate that was imaged and/or etched based on a target pattern. The printed pattern can include, for example, troughs, channels, depressions, edges, or other two and three dimensional features resulting from a lithography process.

As used herein, the term “process model” means a model that includes one or more models that simulate a patterning process. For example, a process model can include an optical model (e.g., that models a lens system/projection system used to deliver light in a lithography process and may include modelling the final optical image of light that goes onto a photoresist), a resist model (e.g., that models physical effects of the resist, such as chemical effects due to the light), and an OPC model (e.g., that can be used to modify target patterns to include sub-resolution resist features (SRAFs), etc.).

In order to improve the patterning process and patterning accuracy, process models are trained using target patterns, mask patterns, substrate images, etc. For example, the process model comprises one or more trained models used in OPC process to generate better mask patterns. For example, OPC assisted by machine learning significantly improves the accuracy of full chip assist feature (e.g., SRAF) placement while keeping consistency and runtime of the mask design under control. A deep convolutional neural network (CNN) is trained using the target layout or target patterns therein, and corresponding continuous transmission mask (CTM) images. These CTM images are optimized using an inverse mask optimization simulation process. The CNN generated SRAF guidance map is then used to place SRAF on full-chip design layout.

When choosing a set of patterns for training, it is desired to select patterns that will be most informative for the model. Currently, several approaches are available for pattern selection. For example, a pattern hashing techniques may be fast, but works best in exact matching, rather than capturing pattern similarity. In another example, unsupervised image based pattern imaging techniques (e.g., Auto-Encoder based) may capture pattern similarities in a higher multi-dimensional latent space, but requires training and is data dependent. In a model simulation based pattern classification and selection technique, aerial image or resist image parameter space may be used that considers similarities from a model simulation perspective. However, the parameter space could be limited and may not clearly distinguish between different design patterns.

In the present embodiment, there is provided a method of pattern selection e.g., from a design layout for training a machine learning model. The pattern selection method herein employs a transformation operation causing embedding of information around a pixel of interest in a pattern in a representation domain. Such embedding of the information may be represented as a group of data points in a representation domain characterized by the mathematical operation. For example, a group of data points having embedded information indicates pixel values associated with features available around the pixel of interest. The transformation discussed herein is computationally less intensive compared to a machine learning based approach for pattern selection. Also, an information metric (e.g., information entropy) may be determined using the group of data points that guides the selection of patterns from a design layout.

Some machine learning based approaches tend to fail a pixel shift test, where after shifting a pattern slightly, the shifted pattern may be treated erroneously as largely different. On the other hand, using the method disclosed herein, the pixel shift test results illustrate better pattern selection. For example, by shifting a window by a certain number of pixels, some patterns may be evaluated as similar and not having sufficient distinctive information. As such, the present method may select fewer but most representative patterns with less unnecessary information. That is, a smaller training data set can be used to achieve high model quality.

According to the present disclosure, transforming a pattern into a representative domain and determining an information metric such as an entropy of the target layout, can significantly improve the pattern selection process by saving substantial computation time and resources. For example, according to present disclosure, the need for expensive physics-based computation for generating CTM used in the error-based approach can be eliminated. Also, the information metric can help eliminate multiple forward passes of the neural network that may be performed in the uncertainty based approach.

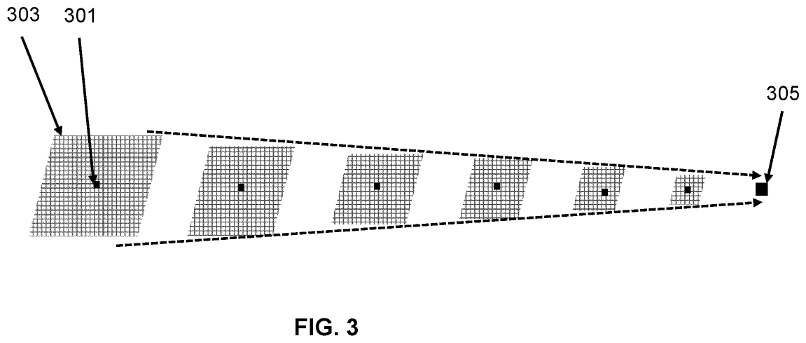

FIG. 3 illustrates an example transformation of a portion 301 of a pattern of interest using a convolution operation e.g., via a convolutional network such as an autoencoder. For example, a progressive convolution using a portion of a pattern 301 transforms proximity information 303 into network weights to generate a pixel 305 with embedded proximity information. Accordingly, a pattern may be represented as a set of pixel-embedded-information. However, such machine learning based convolution operation requires tedious training, especially if trained per-pixel.

According to the present disclosure, a method for pattern selection does not require machine learning or other patterning process simulations. For example, the pattern selection process involves transforming a pattern into a representation domain through a set of basis functions to generate a pattern representation (e.g., a linear pattern representation) for any input pattern. Particularly, a pattern can be represented as a combination of the basis functions with respective weights or coefficients (e.g., linear combination). Such transformation advantageously does not require any training as in auto encoding techniques and thus faster pattern selection can be achieved.

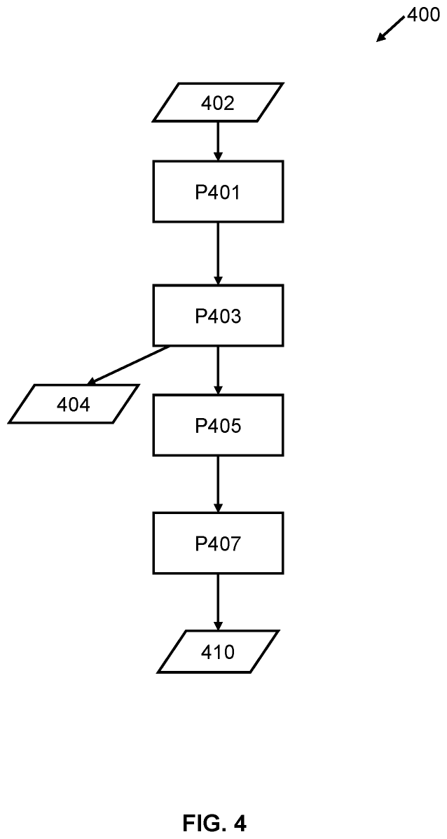

FIG. 4 is a flow chart of an exemplary method 400 for selecting patterns or portions of the patterns from an input, e.g., a target layout including target patterns to be patterning a substrate, according to an embodiment. In an embodiment, the input may be represented in the form of images, vectors, or etc. The selected patterns can be used as training data for training a model associated with a patterning process. The method involves processes P401, P403, P405 and P407.

Process P401 includes obtaining a set of patterns 402 including a first pattern and a second pattern, each pattern of the set of patterns comprising one or more features. In an embodiment, the set of patterns 402 may be obtained from a design layout to be printed on a substrate; a simulated image associated with a patterning process; or an image associated with a patterned substrate. In an embodiment, the simulated image may be an aerial image, a mask image, a resist image, or an etch image obtained via one or more process models (e.g., as discussed with reference to FIG. 2). In an embodiment, the image of the patterned substrate may be a scanning electron microscope (SEM) image of the patterned substrate, simulated or captured by a SEM system.

In an embodiment, the set of patterns 402 may be represented as an image. In this case, the set of patterns 402 may be referred as the image 402. In an embodiment, the image 402 may be an image of a design layout including patterns to be printed on a substrate; or a SEM image of a patterned substrate acquired via a scanning electron microscope (SEM). In an embodiment, the image 402 may be a binary image, a gray scale image, or an n-channel image, where n refers to number of colors used in the image 402 (e.g., 3-channel image with colors red, green and blue (RGB)). For example, a binary image may include pixels assigned value 1 indicating a feature at a pixel location, and value 0 indicating no feature presence at a pixel location. Similarly, the gray scale image may include pixel intensities indicative of presence of absence of a feature of a pattern. In an embodiment, the n-channel image may comprise RGB color channels, which may be indicative of presence or absence of a feature of a pattern. In an embodiment, the color of the RGB can be indicative of a collection of particular features in a pattern.

In an embodiment, a pattern of the set of patterns 402 may include one or more features (e.g. line, holes, etc.) desired to be printed on a substrate. In an embodiment, the one or more features are arranged relative to each other according to circuit design specifications. In an embodiment, a pattern of the set of patterns 402 includes one or more features (e.g., lines, holes, etc.) printed on a substrate. The present disclosure is not limited to a particular image or patterns, or features therein.

Process P403 includes representing a pattern of the set of patterns 402 as a group of data points 404 in a representation domain. In an embodiment, each pattern may be represented as a group of data points 404 in the representative domain. For example, the first pattern may be represented as a first group of data points in the representation domain. The second pattern may be represented as a second group of data points in the representation domain. In an embodiment, each data point of the first group may be indicative of information associated with features within a portion of the first pattern, and each data point of the second group is indicative of information associated with features within a portion of the second pattern. In an embodiment, the information associated with features within a portion of a given pattern of the set of patterns 402 includes pixel values or pixel intensity within the portion of the given pattern. In an embodiment, the pixel values or pixel intensities are associated with a feature within the portion. For example, a high intensity value may indicate a portion of the feature. In an embodiment, the term “given pattern” is generally used to refer to any pattern under consideration from the set of patterns 402.

In an embodiment, representing each pattern as the group of data points 404 in the representation domain includes converting the given pattern by a set of basis functions, the set of basis functions characterizing the representation domain. In an embodiment, upon conversion, the group of data points 404 are a set of coefficients associated with the set of basis functions. In an embodiment, the set of coefficients associated with the set of basis functions correspond to a set of locations of pixels of the given pattern in the representative domain.

In an embodiment, the set of basis functions are a set of orthogonal functions. In an embodiment, the set of basis functions may be Hermite Gaussian modes; Zernike polynomials; Bessel functions, or other functions.

In an embodiment, the converting includes projecting the given pattern of the set of patterns 402 in a linear representation domain. In an embodiment, the projecting includes determining a linear combination of the set of orthogonal functions representing the given pattern of the set of patterns 402. In an embodiment, the representation domain is a Hilbert space domain. Embodiments of the present disclosure are described in detail with reference to a linear representation domain or a Hilbert space. It will be appreciated that the present disclosure is not limited to any specific combination of the basis functions, or any specific set of basis functions.

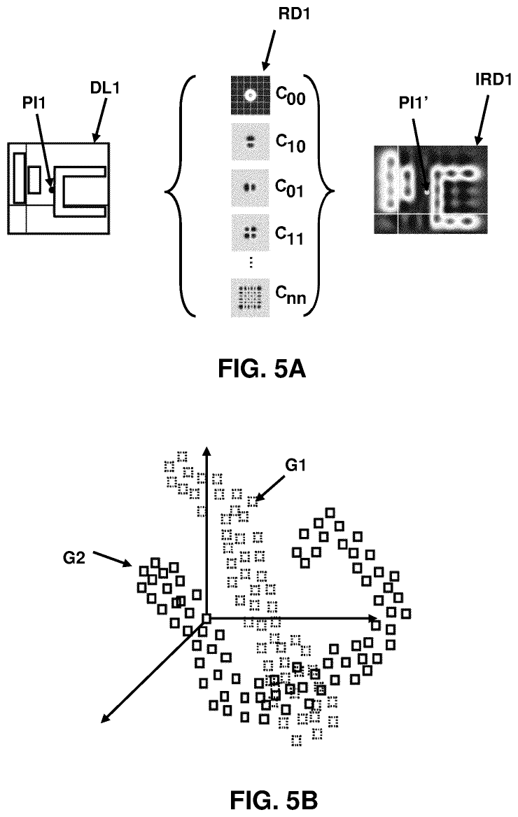

FIG. 5A pictorially depicts an example transformation of a pattern into a representation domain according to an embodiment of the present disclosure. In an embodiment, a functional projection in a Hilbert Space may be denoted by <φ|ψᵢ>, where φ represents the pattern to be represented in the representative domain, and ψᵢ represents the ith order of the basis function to be used in the representation. For such Hilbert space, a projection coefficient may be computed as

$${c}_{i} = < φ \vert {ψ}_{i} > = \frac{\int φ \cdot {ψ}_{i}^{*} dx}{\int {ψ}_{i}^{*} \cdot {ψ}_{i} d x}$$

Thus, a set of projection coefficients C={c₀, c₁, . . . cₙ} can be used as the pattern representation in the representation domain e.g., [symbol] ⁿ space. In this case, the representation is a vector composed of individual coefficients. However, this discussion is merely exemplary. A pattern representation can use various mathematical forms of the projection coefficients without departing from the scope of the present disclosure. Further projecting a pattern onto a Hilbert space can be implemented in any suitable projection technique that is well known in the art.

Process P405 determining a set of distance values of a distance metric corresponding to the set of patterns 402, the set of distance values comprising a first distance value determined between the first group of data points and another group of data points (e.g., a second, a third, a fourth, a fifth, a sixth, etc. group of data points), and the second distance value being determined between the second group of data points and the other group of data points (e.g., a third, a fourth, a fifth, a sixth etc. group of data points). According to embodiments of the present disclosure, the distance metric indicates an amount of mutual information between a given pattern and the other pattern of the set of patterns 402.

In an embodiment, the amount of mutual information between the given pattern and the other pattern indicates how much information in the given pattern is common with the other pattern. A high amount of mutual information indicates a high amount of common information between the given pattern and the other pattern. In an embodiment, the distance metric includes Kullback-Leibler divergence computed using the data points within a group in the representation domain; or k-mean of nearest neighbors computed using the data points within a group in the representation domain. A large distance between the groups indicate a less amount of mutual information between two patterns. For example, farther away the groups from each other lower will be the mutual information between those groups.

Process P407 includes selecting a subset of patterns 410 from the set of patterns 402 using the groups of data points 404 as a guide for mutual information between a given pattern and another pattern of the set of patterns 402. In an embodiment, selecting the subset of patterns may be based on values of the distance metric breaching a distance threshold. For example, when two groups of data points (e.g., groups G1 and G2 in FIG. 5B) are far from each other (e.g., greater than the distance threshold), the groups collectively are considered more informative with respect to machine learning training compared to groups that are closer (e.g., less than the distance threshold) to each other.

In an embodiment, selecting the subset of patterns includes selecting a plurality of patterns from the set of patterns 402 based on a total entropy of the selected patterns. In an embodiment, selecting includes determining the total entropy as a combination of information entropy associated with each group of data points corresponding to each pattern of the set of patterns 402. In an embodiment, the information entropy may be computed directly on the group of data points due to problem with a sparse high-dimensionality, where computation may fail when a unit volume of a bounding box tends to zero as the dimensions increase.

In an embodiment, selecting the subset of patterns from the set of patterns 402 includes selecting a plurality of groups from the groups representing the set of patterns 402. For example, each selected group has a value of the distance metric breaching the distance threshold. For the selected groups, a determination can be made whether information entropy in the representation domain reaches a certain criteria, e.g., maximized. However, the criteria can be in any form with respect to the total entropy without departing from the scope of the present disclosure. For example, responsive to the information entropy not being maximized, one or more groups (that were previously not selected) are added to the selected plurality of groups or a group from the selected plurality of groups is removed. The adding or removing of groups can be repeated until the information entropy is maximized (or within the specified range) and a final selection of group is obtained. Then, a plurality of patterns or the subset of patterns are selected corresponding to the selected plurality of groups.

There are multiple ways of calculating entropies in different representation domain. In some embodiments, using the Hilbert space coefficients (also referred as data points) to calculate a total entropy. In some embodiments, pixel values in a different representative domain may be used to calculate entropy. In some embodiments, an entropy associated with a pattern may be determined based on pixel intensities within a portion of the image 402 representing the subset of patterns. In an embodiment, the entropy is indicative of non-homogeneity of each of the plurality of patterns 402. For example, the non-homogeneity of patterns indicate the patterns are substantially different from each other and hence more informative for training purposes. In an embodiment, the entropy is at least one of an information entropy, Renyi entropy, or differential entropy.

In an embodiment, the information entropy comprises a sum of products of a probability of an outcome of a plurality of possible outcomes associated with a portion of an image and a logarithmic function of the probability of the outcome. In an embodiment, the information entropy is computed by following equation:

$$H ( X ) = - {\sum }_{i} {P}_{X} ( {x}_{i} ) log {P}_{X} ( {x}_{i} )$$

In the above equation, H(X) is the entropy of the portion of the image, xᵢ represents possible outcomes associated with subset of patterns 410, each outcome having a probability P_{X}(xᵢ). For example, in binary image, the possible outcomes xi, are x1 and x2, where x1 is a white pixel (e.g., pixel intensity value is 0) and x2 is a black pixel (e.g., pixel intensity value is 1). In an embodiment, the subset of patterns 410 can be a gray scale image, in which case the possible outcomes xi, wherein can vary from 0 to 255.

For example, the probability P_{X}(xᵢ) is computed as follows: P_{X}(xᵢ)=(number of pixels with intensity level i in a sliding window)/(number of pixels in the sliding window). The associated entropy value is then typically assigned to a center pixel in the sliding window. So, for the binary image example, the entropy expression is largest if 50% of the pixels are white and 50% are black (i.e. P_{X}(x₁)=P_{X}(x₂)=0.5), whereas it is smallest when only a single color is present in the entire sliding window (i.e. P_{X}(x₁)=1 and P_{X}(x₂)=0 or vice-versa).

In an embodiment, the possible outcomes comprises at least one of: a binary value assigned to a pixel of the image, a first value being indicative of presence of a pattern within the image and a second value being indicative of absence a pattern within the image; a gray scale value assigned to a pixel of the image; or number of colors assigned to pixels of the image 402.

In an embodiment, the entropy can be calculated for each channel and the entropy for each channel can be compared for selection of patterns. In an embodiment, the multi-channel image can be a collection of SEM images at the same location but with different SEM settings. The information metric per channel can be computed. The entropy can be combined as a weighted average over all channels, or selected as a worst case of the metric among different channels.

In an embodiment, the determining of the distance metric or information entropy does not need to include simulating, one or more of the plurality of patterns 402, a process model associated with a patterning process, or simulating, using one or more of the plurality of patterns 402, a machine learning model associated with the patterning process. The metric can be directly applied to the target layout, a portion of the target layout or patterns therein. In an embodiment, the target layout can be provided in GDS format.

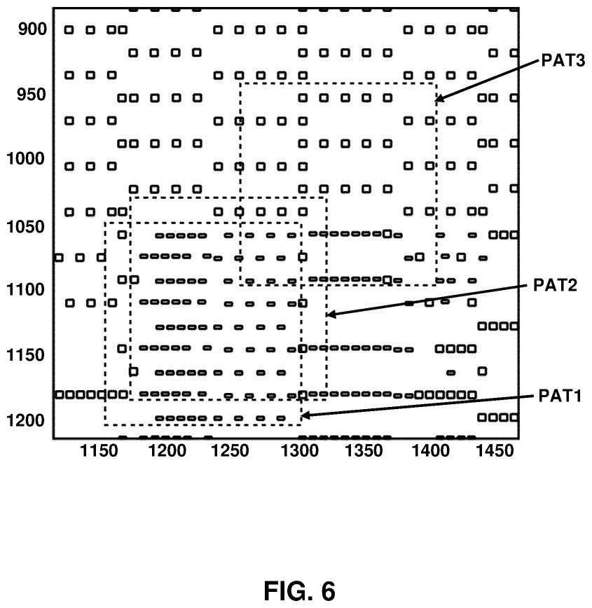

FIG. 6 illustrates an example of subset of plurality of patterns selected from an exemplary design layout. For example, according to method 400 discussed above, several portion of the design layout may be transformed into groups data points in a representation domain (e.g., see FIGS. 5A and 5B). Based on a distance between groups of data points, a subset of patterns may be selected based on the total entropy, e.g., that correspond to a maximum entropy. Referring to FIG. 6, features inside boxes PAT1, PAT2, and PAT3 represent a plurality of patterns, from which a subset PAT1 and PAT3 may be selected based on a group of data points in the representation domain corresponding to the patterns PAT1, PAT2, and PAT3. In the present example, a first group of data points (not shown) may corresponding to the pattern PAT1 and a second group of data points (not shown) may corresponding to the pattern PAT2. A distance between the first group and the second group may be less than a distance threshold or may not correspond to maximizing information entropy between pattern PAT1 and PAT2. As such, the pattern PAT2 may be omitted or not selected as a subset of pattern.

In an embodiment, the method may further include a process for providing the selected sub-set of patterns 410 as training data for training a model associated with a patterning process. The present disclosure is not limited to the specific use of the outputted sub-patterns. In an embodiment, the sub-set of patterns can be used to improve one or more aspects of the patterning process including but not limited to improving training of aerial image model, mask model, resist model, OPC process, metrology related models or other models related to patterning process.

In an embodiment, the method 400 may further include steps for training, using the sub-set of patterns 410 as training data, a model associated with the patterning process. In an embodiment, the training includes training a model configured to generate optical proximity correction structures associated with the plurality of patterns 402 of a design layout. For example, the optical proximity correction structures includes main features corresponding to the plurality of patterns 402 of the design layout; or assist features surrounding the plurality of patterns 402 of the design layout.

In an embodiment, another variation of a method for selecting patterns and generating training data therefrom can be implemented as follows. In an embodiment, the method includes obtaining a set of patterns; representing each pattern of the set of patterns as a group of data points in a representation domain; and selecting a subset of patterns from the set of patterns based on the groups of data points as a guide for mutual information between a given pattern and another pattern of the set of patterns. As discussed above, the patterns may be represented in a representation domain using a set of basis functions. For example, representing patterns in Hilbert space.

In an embodiment, there is provided a method for representing patterns in a representation domain. The method includes obtaining a set of patterns, each pattern comprising one or more features; and converting each pattern of the set of patterns into a group of data points in a representation domain, each data point indicative of information associated with features within a portion of a given pattern of the set of patterns.

In an embodiment, representing each pattern as the group of data points in the representation domain includes converting by a set of basis functions the given pattern, the set of basis functions characterizing the representation domain. In an embodiment, the set of basis functions are a set of orthogonal functions. In an embodiment, upon conversion, the group of data points are a set of coefficients associated with the set of basis functions. In an embodiment, the set of coefficients associated with the set of basis functions correspond to a set of locations of pixels of the given pattern in the representative domain.

In an embodiment, the converting includes projecting the given pattern of the set of patterns in linear representation domain. In an embodiment, the projecting includes determining a linear combination of the set of orthogonal functions representing the given pattern of the set of patterns. In an embodiment, the set of basis functions comprises at least one of: Hermite Gaussian modes; Zernike polynomials; or Bessel functions.

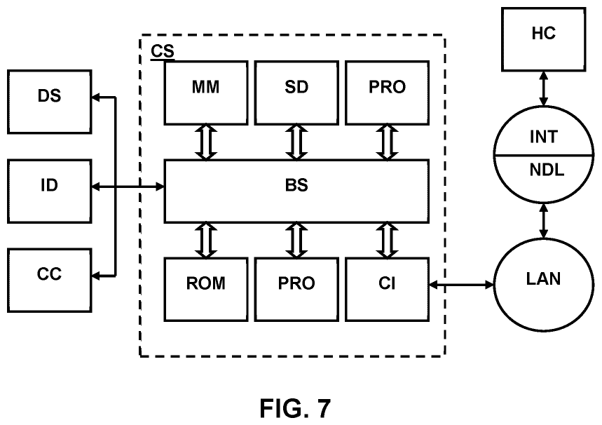

In an embodiment, the methods discussed herein may be provided as one or more computer program products or a non-transitory computer readable medium having instructions recorded thereon, the instructions when executed by a computer implementing the operation of the method 400 discussed above. For example, an example computer system CS in FIG. 7 includes a non-transitory computer-readable media (e.g., memory) comprising instructions that, when executed by one or more processors (e.g., 104), cause operations for selecting patterns from a target layout. In an embodiment, the instructions include obtaining a set of patterns; representing each pattern of the set of patterns as a group of data points in a representation domain; and selecting a subset of patterns from the set of patterns based on the groups of data points as a guide for mutual information between a given pattern and another pattern of the set of patterns.

In an embodiment, the instructions includes obtaining a set of patterns including a first pattern and a second pattern, each pattern of the set of patterns comprising one or more features; representing each pattern of the set of patterns as a group of data points in a representation domain; determining a set of distance values of a distance metric corresponding to the set of patterns (e.g., the set of distance values comprising a first distance value determined between the first group of data points and another group of data points, and the second distance value being determined between the second group of data points and the other group of data points); and selecting, based on the values of the distance metric breaching a distance threshold, a subset of patterns from the set of patterns. In an embodiment, the distance metric being indicative of an amount of mutual information between a given pattern and the other pattern of the set of patterns. In an embodiment, the first pattern represented as a first group of data points in the representation domain, and the second pattern represented as a second group of data points in the representation domain. In an embodiment, each data point of the first group being indicative of information associated with features within a portion of the first pattern, and each data point of the second group is indicative of information associated with features within a portion of the second pattern.

According to present disclosure, the combination and sub-combinations of disclosed elements constitute separate embodiments. For example, a first combination includes determining a group of data points and selecting patterns based on the group of data points. The sub-combination may include determining a distance metric between groups. A sub-combination may include determining an information entropy (e.g., using the entropy equation discussed above) associated with a subset of patterns. In another combination, the selected pattern can be employed in an inspection process, training a machine learning model related to a patterning process, determining OPC, or SMO using the selected pattern.

FIG. 7 is a block diagram of an example computer system CS, according to an embodiment.

Computer system CS includes a bus BS or other communication mechanism for communicating information, and a processor PRO (or multiple processor) coupled with bus BS for processing information. Computer system CS also includes a main memory MM, such as a random access memory (RAM) or other dynamic storage device, coupled to bus BS for storing information and instructions to be executed by processor PRO. Main memory MM also may be used for storing temporary variables or other intermediate information during execution of instructions to be executed by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a cathode ray tube (CRT) or flat panel or touch panel display for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

According to one embodiment, portions of one or more methods described in the disclosure may be performed by computer system CS in response to processor PRO executing one or more sequences of one or more instructions contained in main memory MM. Such instructions may be read into main memory MM from another computer-readable medium, such as storage device SD. Execution of the sequences of instructions contained in main memory MM causes processor PRO to perform the process steps described herein. One or more processors in a multi-processing arrangement may also be employed to execute the sequences of instructions contained in main memory MM. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the features described herein. Transitory computer-readable media can include a carrier wave or other propagating electromagnetic signal.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) both use electrical, electromagnetic or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

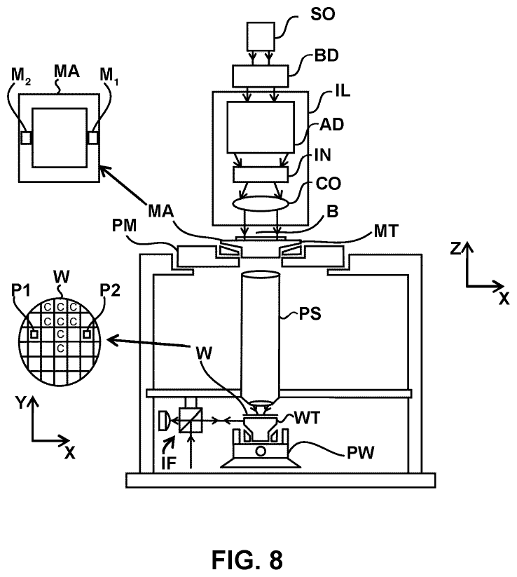

FIG. 8 is a schematic diagram of a lithographic projection apparatus, according to an embodiment.

The lithographic projection apparatus can include an illumination system IL, a first object table MT, a second object table WT, and a projection system PS.

Illumination system IL, can condition a beam B of radiation. In this particular case, the illumination system also comprises a radiation source SO.

First object table (e.g., patterning device table) MT can be provided with a patterning device holder to hold a patterning device MA (e.g., a reticle), and connected to a first positioner to accurately position the patterning device with respect to item PS.

Second object table (substrate table) WT can be provided with a substrate holder to hold a substrate W (e.g., a resist-coated silicon wafer), and connected to a second positioner to accurately position the substrate with respect to item PS.

Projection system (“lens”) PS (e.g., a refractive, catoptric or catadioptric optical system) can image an irradiated portion of the patterning device MA onto a target portion C (e.g., comprising one or more dies) of the substrate W.

As depicted herein, the apparatus can be of a transmissive type (i.e., has a transmissive patterning device). However, in general, it may also be of a reflective type, for example (with a reflective patterning device). The apparatus may employ a different kind of patterning device to classic mask; examples include a programmable mirror array or LCD matrix.

The source SO (e.g., a mercury lamp or excimer laser, LPP (laser produced plasma) EUV source) produces a beam of radiation. This beam is fed into an illumination system (illuminator) IL, either directly or after having traversed conditioning means, such as a beam expander Ex, for example. The illuminator IL may comprise adjusting means AD for setting the outer and/or inner radial extent (commonly referred to as σ-outer and σ-inner, respectively) of the intensity distribution in the beam. In addition, it will generally comprise various other components, such as an integrator IN and a condenser CO. In this way, the beam B impinging on the patterning device MA has a desired uniformity and intensity distribution in its cross-section.

In some embodiments, source SO may be within the housing of the lithographic projection apparatus (as is often the case when source SO is a mercury lamp, for example), but that it may also be remote from the lithographic projection apparatus, the radiation beam that it produces being led into the apparatus (e.g., with the aid of suitable directing mirrors); this latter scenario can be the case when source SO is an excimer laser (e.g., based on KrF, ArF or F2 lasing).

The beam PB can subsequently intercept patterning device MA, which is held on a patterning device table MT. Having traversed patterning device MA, the beam B can pass through the lens PL, which focuses beam B onto target portion C of substrate W. With the aid of the second positioning means (and interferometric measuring means IF), the substrate table WT can be moved accurately, e.g. so as to position different target portions C in the path of beam PB. Similarly, the first positioning means can be used to accurately position patterning device MA with respect to the path of beam B, e.g., after mechanical retrieval of the patterning device MA from a patterning device library, or during a scan. In general, movement of the object tables MT, WT can be realized with the aid of a long-stroke module (coarse positioning) and a short-stroke module (fine positioning). However, in the case of a stepper (as opposed to a step-and-scan tool) patterning device table MT may just be connected to a short stroke actuator, or may be fixed.

The depicted tool can be used in two different modes, step mode and scan mode. In step mode, patterning device table MT is kept essentially stationary, and an entire patterning device image is projected in one go (i.e., a single “flash”) onto a target portion C. Substrate table WT can be shifted in the x and/or y directions so that a different target portion C can be irradiated by beam PB.

In scan mode, essentially the same scenario applies, except that a given target portion C is not exposed in a single “flash.” Instead, patterning device table MT is movable in a given direction (the so-called “scan direction”, e.g., the y direction) with a speed v, so that projection beam B is caused to scan over a patterning device image; concurrently, substrate table WT is simultaneously moved in the same or opposite direction at a speed V=Mv, in which M is the magnification of the lens PL (typically, M=¼ or ⅕). In this manner, a relatively large target portion C can be exposed, without having to compromise on resolution.

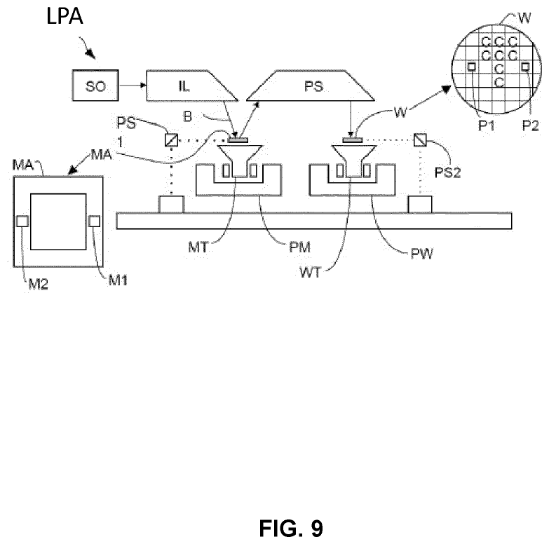

FIG. 9 is a schematic diagram of another lithographic projection apparatus (LPA), according to an embodiment.

LPA can include source collector module SO, illumination system (illuminator) IL configured to condition a radiation beam B (e.g. EUV radiation), support structure MT, substrate table WT, and projection system PS.

Support structure (e.g. a patterning device table) MT can be constructed to support a patterning device (e.g. a mask or a reticle) MA and connected to a first positioner PM configured to accurately position the patterning device;

Substrate table (e.g. a wafer table) WT can be constructed to hold a substrate (e.g. a resist coated wafer) W and connected to a second positioner PW configured to accurately position the substrate.

Projection system (e.g. a reflective projection system) PS can be configured to project a pattern imparted to the radiation beam B by patterning device MA onto a target portion C (e.g. comprising one or more dies) of the substrate W.

As here depicted, LPA can be of a reflective type (e.g. employing a reflective patterning device). It is to be noted that because most materials are absorptive within the EUV wavelength range, the patterning device may have multilayer reflectors comprising, for example, a multi-stack of molybdenum and silicon. In one example, the multi-stack reflector has a 40 layer pairs of molybdenum and silicon where the thickness of each layer is a quarter wavelength. Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

Illuminator IL can receive an extreme ultra violet radiation beam from source collector module SO. Methods to produce EUV radiation include, but are not necessarily limited to, converting a material into a plasma state that has at least one element, e.g., xenon, lithium or tin, with one or more emission lines in the EUV range. In one such method, often termed laser produced plasma (“LPP”) the plasma can be produced by irradiating a fuel, such as a droplet, stream or cluster of material having the line-emitting element, with a laser beam. Source collector module SO may be part of an EUV radiation system including a laser, not shown in FIG. 9, for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation.

In such cases, the laser may not be considered to form part of the lithographic apparatus and the radiation beam can be passed from the laser to the source collector module with the aid of a beam delivery system comprising, for example, suitable directing mirrors and/or a beam expander. In other cases, the source may be an integral part of the source collector module, for example when the source is a discharge produced plasma EUV generator, often termed as a DPP source.

Illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B can be incident on the patterning device (e.g., mask) MA, which is held on the support structure (e.g., patterning device table) MT, and is patterned by the patterning device. After being reflected from the patterning device (e.g. mask) MA, the radiation beam B passes through the projection system PS, which focuses the beam onto a target portion C of the substrate W. With the aid of the second positioner PW and position sensor PS2 (e.g. an interferometric device, linear encoder or capacitive sensor), the substrate table WT can be moved accurately, e.g. so as to position different target portions C in the path of radiation beam B. Similarly, the first positioner PM and another position sensor PS1 can be used to accurately position the patterning device (e.g. mask) MA with respect to the path of the radiation beam B. Patterning device (e.g. mask) MA and substrate W may be aligned using patterning device alignment marks M1, M2 and substrate alignment marks P1, P2.

The depicted apparatus LPA could be used in at least one of the following modes, step mode, scan mode, and stationary mode.

In step mode, the support structure (e.g. patterning device table) MT and the substrate table WT are kept essentially stationary, while an entire pattern imparted to the radiation beam is projected onto a target portion C at one time (i.e. a single static exposure). The substrate table WT is then shifted in the X and/or Y direction so that a different target portion C can be exposed.

In scan mode, the support structure (e.g. patterning device table) MT and the substrate table WT are scanned synchronously while a pattern imparted to the radiation beam is projected onto target portion C (i.e. a single dynamic exposure). The velocity and direction of substrate table WT relative to the support structure (e.g. patterning device table) MT may be determined by the (de-)magnification and image reversal characteristics of the projection system PS.

In stationary mode, the support structure (e.g. patterning device table) MT is kept essentially stationary holding a programmable patterning device, and substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

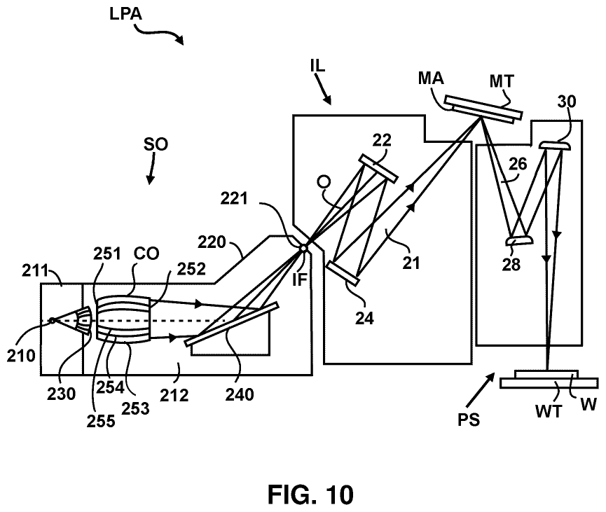

FIG. 10 is a detailed view of the lithographic projection apparatus, according to an embodiment.

As shown, LPA can include the source collector module SO, the illumination system IL, and the projection system PS. The source collector module SO is constructed and arranged such that a vacuum environment can be maintained in an enclosing structure 220 of the source collector module SO. An EUV radiation emitting plasma 210 may be formed by a discharge produced plasma source. EUV radiation may be produced by a gas or vapor, for example Xe gas, Li vapor or Sn vapor in which the very hot plasma 210 is created to emit radiation in the EUV range of the electromagnetic spectrum. The very hot plasma 210 is created by, for example, an electrical discharge causing at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap) which is positioned in or behind an opening in source chamber 211. The contaminant trap 230 may include a channel structure. Contamination trap 230 may also include a gas barrier or a combination of a gas barrier and a channel structure. The contaminant trap or contaminant barrier 230 further indicated herein at least includes a channel structure, as known in the art.

The collector chamber 211 may include a radiation collector CO which may be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point IF along the optical axis indicated by the dot-dashed line ‘O’. The virtual source point IF is commonly referred to as the intermediate focus, and the source collector module is arranged such that the intermediate focus IF is located at or near an opening 221 in the enclosing structure 220. The virtual source point IF is an image of the radiation emitting plasma 210.

Subsequently the radiation traverses the illumination system IL, which may include a facetted field mirror device 22 and a facetted pupil mirror device 24 arranged to provide a desired angular distribution of the radiation beam 21, at the patterning device MA, as well as a desired uniformity of radiation intensity at the patterning device MA. Upon reflection of the beam of radiation 21 at the patterning device MA, held by the support structure MT, a patterned beam 26 is formed and the patterned beam 26 is imaged by the projection system PS via reflective elements 28, 30 onto a substrate W held by the substrate table WT.

More elements than shown may generally be present in illumination optics unit IL and projection system PS. The grating spectral filter 240 may optionally be present, depending upon the type of lithographic apparatus. Further, there may be more mirrors present than those shown in the figures, for example there may be 1-6 additional reflective elements present in the projection system PS than shown in FIG. 10.

Collector optic CO, as illustrated in FIG. 10, is depicted as a nested collector with grazing incidence reflectors 253, 254 and 255, just as an example of a collector (or collector mirror). The grazing incidence reflectors 253, 254 and 255 are disposed axially symmetric around the optical axis O and a collector optic CO of this type may be used in combination with a discharge produced plasma source, often called a DPP source.

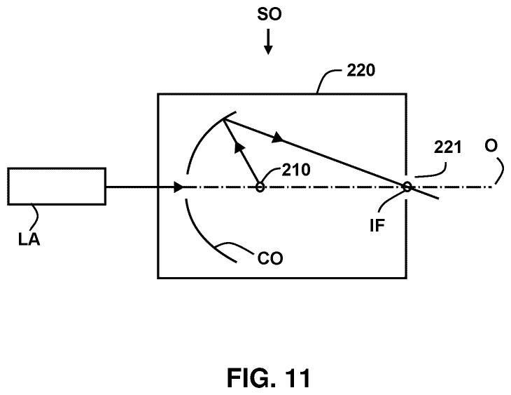

FIG. 11 is a detailed view of source collector module SO of lithographic projection apparatus LPA, according to an embodiment.

Source collector module SO may be part of an LPA radiation system. A laser LA can be arranged to deposit laser energy into a fuel, such as xenon (Xe), tin (Sn) or lithium (Li), creating the highly ionized plasma 210 with electron temperatures of several 10's of eV. The energetic radiation generated during de-excitation and recombination of these ions is emitted from the plasma, collected by a near normal incidence collector optic CO and focused onto the opening 221 in the enclosing structure 220.

According to the present disclosure, a method for pattern selection involves transforming a pattern into a representation domain, such as optical system of an illumination source based domain, through a set of basis functions to generate a pattern representation (e.g., a linear pattern representation) for any input pattern. Particularly, a pattern can be represented using a set of transmission cross coefficients (TCCs), which are representative of optical characteristics of an illumination source of the lithographic apparatus, such as electromagnetic field (EMF) excitations of various portions of the pattern. Such transformation is readily computable (e.g., once the configuration of the illumination source is known), is more accurate than conventional representations and therefore, provides an improved pattern similarity analysis for a better selection of representative patterns. Such transformation advantageously does not require any training as in auto encoding techniques and thus faster pattern selection can be achieved.

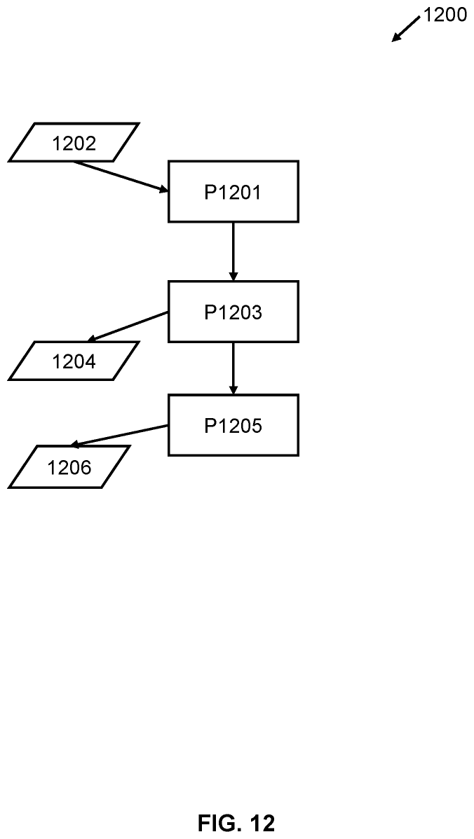

FIG. 12 is a flowchart of an exemplary method for selecting patterns from a target layout based on pattern representation in a source-based representative domain, according to an embodiment. In an embodiment, the input may be represented in the form of images, vectors, etc. The selected patterns may be used for various purposes, e.g., as training data for training or calibrating a model associated with a patterning process.

In process P1201, a first set of patterns 1202 is obtained. In some embodiments, the first set of patterns 1202 may be obtained from a design layout to be printed on a substrate; a simulated image associated with a patterning process; or an image associated with a patterned substrate. In some embodiments, the simulated image may be an aerial image, a mask image, a resist image, or an etch image obtained via one or more process models (e.g., as discussed with reference to FIG. 2). In some embodiments, the image of the patterned substrate may be a SEM image of the patterned substrate, simulated or captured by a SEM system.

In some embodiments, the first set of patterns 1202 may be represented as an image. In this case, the first set of patterns 1202 may be referred to as an image 1202. In some embodiments, the image 1202 may be an image of a design layout including patterns to be printed on a substrate; or a SEM image of a patterned substrate acquired via a SEM. In some embodiments, the image 1202 may be a binary image, a gray scale image, or an n-channel image, where n refers to number of colors used in the image 1202 (e.g., 3-channel image with colors red, green and blue (RGB)). For example, a binary image may include pixels assigned value “1” indicating a feature at a pixel location, and value “0” indicating no feature presence at a pixel location. Similarly, the gray scale image may include pixel intensities indicative of presence or absence of a feature of a pattern. In some embodiments, the n-channel image may comprise RGB color channels, which may be indicative of presence or absence of a feature of a pattern. In some embodiments, the color of the RGB can be indicative of a collection of particular features in a pattern.

In some embodiments, a pattern of the first set of patterns 402 may include one or more features (e.g., line, holes, etc.) desired to be printed on a substrate. The features may be arranged relative to each other according to circuit design specifications. The present disclosure is not limited to a particular image or patterns, or features therein.

In process P1203, a pattern of the first set of patterns 402 may be represented in a representation domain. For example, the pattern may be represented in Hilbert Space domain such as an electromagnetic field (EMF) domain. In some embodiments, representing a pattern in a representation domain includes representing the pattern as a group of data points 1204. In some embodiments, a data point is indicative of information associated with features within a portion of the pattern. In some embodiments, representing a given pattern as the group of data points 1204 in the representation domain includes converting the given pattern by a set of basis functions, which characterize the representation domain. Upon conversion, the group of data points 1204 may correspond to a set of coefficients associated with the set of basis functions. In some embodiments, the set of basis functions are a set of orthogonal functions. In an embodiment, the converting includes projecting the given pattern in a linear representation domain, which includes determining a linear combination of the set of orthogonal functions representing the given pattern. For example, a pattern may be projected onto an EMF domain using SOCS TCCs as basis functions. Upon conversion, each pixel of the pattern is represented using a vector (e.g., N-dimensional vector of TCCs) that is representative of EMF excitation at the pixel, and the pattern is represented as a group of vectors (e.g., group of data points 1204). The details of representing a pattern in a linear representation domain or a Hilbert space are described at least with reference to FIG. 5A above. In FIG. 5A, the ψᵢ, which represents the i^{th} order of the basis function to be used in the representation may include TCC basis function, e.g., TCCᵢ. Such a representation of the set of projection coefficients C={c₀, c₁, . . . cₙ} can be used as the pattern representation in the representation domain and it may contain necessary information about how a pattern-pixel is represented in an EMF domain. An image of the pattern may be reconstructed (although lossy-which is representative of diffraction loss of the illumination source) using the coefficient. The reconstruction may be expressed as:

$${\sum }_{i}^{N} {c}_{i} {TCC}_{i} ( x , y ) \qquad ( Eq . A )$$

Where cᵢ is the i^{th} order coefficient, TCCᵢ is the i^{th} order basis function, and (x,y) is the location of a pixel.

The following paragraphs describe additional details in projecting a pattern in an illumination source-based representation domain that describes characteristics of the source with reference to a pattern (e.g., source response to a pattern). In some embodiments, a pattern from the first set of patterns 1202 may be represented in a source-based representation domain, such as an EMF domain, using sum of coherent systems (SOCS) TCCs as basis functions. The TCC describes EMF excitation of a portion of the pattern. For example, the source characteristics of the lithographic apparatus may be modeled using Hopkins' imaging formula, which computes a TCC of the partially coherent source. The TCC may then be decomposed into a discrete set of coherent systems (e.g., N SOCS TCCs) with orthogonal transfer functions. The set of SOCS TCCs represent the EMF transfer functions of the individual coherent systems, wherein the final imaging intensity (e.g., aerial image intensity associated with a pattern) may be determined as the sum of individual intensities. The computation of the aerial image intensity may be represented as follows:

$${AI}_{i} = {\sum }_{k = 0}^{n} {λ}_{k} {\vert {M}_{i} \cdot {TCC}_{k} \vert}^{2} \qquad ( Eq . A )$$

Where i: pixel order
TCCₖ: Spatial SOCS TCC of the k^{th} order (source dependent)
λₖ: TCC k^{th} order eigen value (source dependent)
M: spatial Mask clipped at TCC size

In some embodiments, projecting a pattern in the EMF domain using the SOCS TCCs as basis function includes representing a pixel of the pattern using a set of TCCs (e.g., N-dimensional vector of SOCS TCCs). The vector represents EMF excitation at the pixel based on a proximity of the pixel. That is, the vector is indicative of how the proximity of the pixel impacts the EMF excitation at the pixel. Each element of the vector corresponds to a projection of the pixel to a TCC of the N SOCS TCCs.

Since a pattern may be represented by its pixels, and each pixel may be represented using a vector of SOCS TCCs, the pattern may be represented as a group of vectors or a cloud of vectors, e.g., as illustrated with FIG. 5B. For example, group G1 may represent a group of vectors of a first pattern and group G2 may represent a group of vectors of a second pattern from the first set of patterns 1202, and the axes may correspond to representation domain (e.g., EMF value).

After representing the patterns as a group of vectors or group of data points 1204, at process P1205, a second set of patterns 1206 may be selected from the first set of patterns 1202 as representative patterns based on one or more criteria. In some embodiments, the groups of vectors of the first set of patterns 1204 may be analyzed for pattern similarity and one or more metrics, such as a distance metric between two groups of vectors, that is indicative of the pattern similarity may be determined. If the metric satisfies a criterion (e.g., distance metric satisfies (e.g., exceeds) a distance threshold), the pattern group may be considered different enough to be selected as representative patterns than the pattern group for which the metric does not satisfy the criterion. In some embodiments, selecting the second set of patterns 1206 may be based on a total entropy of the selected patterns. Additional details with respect to selecting the second set of patterns 1206 are described at least with reference to FIG. 4 (e.g., process P405 and P407), FIG. 5B and FIG. 6 above.

The second set of patterns 1206 may be used for various purposes. For example, as described at least with reference to FIG. 4, the second set of patterns 1206 may be used in configuring (e.g., training or calibrating) a model associated with a patterning process. The present disclosure is not limited to the specific use of the selected second set of patterns 1206. The second set of patterns 1206 may be used to improve one or more aspects of the patterning process such as improving performance of aerial image model, mask model, resist model, OPC process, metrology related models or other models related to patterning process.

Note that while FIG. 12 describes representing the pattern in a representation domain that is characterized by an optical system or illumination source of a lithographic apparatus (e.g., a source response to a pattern), the representation domain is not limited to the optical system. The representation domain may be characterized based on any lithographic apparatus or process characteristics, such as a photoresist domain (e.g., response of a photoresist to a pattern).

The concepts disclosed herein may simulate or mathematically model any generic imaging system for imaging sub wavelength features, and may be especially useful with emerging imaging technologies capable of producing increasingly shorter wavelengths. Emerging technologies already in use include EUV (extreme ultra violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-50 nm by using a synchrotron or by hitting a material (either solid or a plasma) with high energy electrons in order to produce photons within this range.

Embodiments of the present disclosure can be further described by the following clauses.

1. A non-transitory computer-readable medium configured to select patterns based on mutual information between the patterns for training machine learning models related to semiconductor manufacturing, the medium comprising instructions stored therein that, when executed by one or more processors, cause operations comprising:
obtaining a set of patterns including a first pattern and a second pattern, each pattern of the set of patterns comprising one or more features;
representing each pattern of the set of patterns as a group of data points in a representation domain, the first pattern represented as a first group of data points in the representation domain, and the second pattern represented as a second group of data points in the representation domain, each data point of the first group being indicative of information associated with features within a portion of the first pattern, and each data point of the second group is indicative of information associated with features within a portion of the second pattern;
determining a set of distance values of a distance metric corresponding to the set of patterns, the set of distance values comprising a first distance value determined between the first group of data points and another group of data points, and the second distance value being determined between the second group of data points and the other group of data points, the distance metric being indicative of an amount of mutual information between a given pattern and the other pattern of the set of patterns; and
selecting, based on the values of the distance metric breaching a distance threshold, a subset of patterns from the set of patterns.

2. The medium of clause 1, wherein the set of patterns comprises patterns obtained from: a design layout desired to be printed on a substrate;
a simulated image associated with a patterning process; or an image associated with a patterned substrate.

3. The medium of clause 2, wherein the simulated image comprises at least one of: an aerial image, a mask image, a resist image, or an etch image.

4. The medium of clause 2, wherein the image of the patterned substrate comprises a scanning electron microscope (SEM) image of the patterned substrate.

5. The medium of any of clauses 1-4, wherein the information associated with features within a portion of the given pattern of the set of patterns comprises:
pixel values within the portion of the given pattern, the pixel values indicative of intensity associated with a feature within the portion.

6. The medium of any of clauses 1-5, wherein the amount of mutual information between the given pattern and the other pattern indicates how much information in the given pattern is common with the other pattern, a high amount of mutual information indicates a high amount of common information between the given pattern and the other pattern.

7. The medium of any of clauses 1-6, wherein representing each pattern as the group of data points in the representation domain comprises:
converting by a set of basis functions the given pattern, the set of basis functions characterizing the representation domain.

8. The medium of clause 7, wherein upon conversion, each pixel of the given corresponds to a set of coefficients associated with the set of basis functions.

9. The medium of clause 8, wherein the set of coefficients associated with the set of basis functions correspond to a set of TCCs.

10. The medium of clause 8, wherein the set of basis functions includes a set of TCC functions.

11. The medium of clause 7, wherein upon conversion, the group of data points correspond to a set of coefficients associated with the set of basis functions.

12. The medium of clause 11, wherein the set of coefficients associated with the set of basis functions correspond to a set of locations of pixels of the given pattern in the representative domain.

13. The medium of any of clauses 7-12, wherein the set of basis functions are a set of orthogonal functions.

14. The medium of any of clauses 7-13, wherein the converting comprises:
projecting the given pattern of the set of patterns in a linear representation domain.

15. The medium of clause 14, wherein the projecting comprises:
determining a linear combination of the set of orthogonal functions representing the given pattern of the set of patterns.

16. The medium of any of clauses 7-15, wherein the set of basis functions comprises at least one of:
Hermite Gaussian modes;
Zernike polynomials; or
Bessel functions.

17. The medium of any of clauses 1-16, wherein the representation domain is a Hilbert space domain.

18. The medium of any of clauses 1-16, wherein selecting the subset of patterns comprises selecting a plurality of patterns from the set of patterns based on a total entropy of the selected patterns.

19. The medium of clause 18, wherein selecting comprises:
determining the total entropy as a combination of information entropy associated with each group of data points corresponding to each pattern of the set of patterns.

20. The medium of clause 19, wherein selecting the subset of patterns from the set of patterns comprises:
selecting a plurality of groups from the groups representing the set of patterns, each selected group having a value of the distance metric breaching the distance threshold; and
determining, for the selected groups, whether information entropy the representation domain meet a prescribed criteria;
responsive to the information entropy not meeting the prescribed criteria, adding other group to the selected plurality of groups or removing a group from the selected plurality of groups and repeating steps; and
selecting a plurality of patterns corresponding to the selected plurality of groups.

21. The medium of any of clauses 1-20, wherein the distance metric comprises:
Kullback-Leibler divergence computed using the data points within a group in the representation domain; or
k-mean of nearest neighbors computed using the data points within a group in the representation domain.

22. The medium of any of clauses 1-21, further comprising:
training, based on the subset of patterns, a machine learning model configured to determine characteristics of a patterning process.

23. The medium of any of clauses 1-22, wherein the machine learning model is configured to determine characteristics of an illumination source of a lithography apparatus, a mask pattern of a mask, a projection system of the lithography apparatus, or a resist used for printing pattern on a substrate.

24. The medium of any of clauses 1-23, wherein representing each pattern as the data points in the representation domain does not include using a machine learning model.

25. The medium of clause 1, wherein the representation domain corresponds to electromagnetic functions.

26. The medium of clause 25, wherein the electromagnetic functions are a set of transmission cross coefficient (TCC) functions associated with an illumination source of a lithographic apparatus that is used to print the first set of patterns on a substrate.

27. The medium of clause 26, wherein representing each pattern includes:
representing a pixel of a pattern of the set of patterns as a pattern vector with each element in the pattern vector corresponding to a projection of the pixel at a TCC of the set of TCC functions.

28. The medium of clause 27, wherein the pattern vector is indicative of an EMF excitation of the corresponding pixel.

29. The medium of clause 27, wherein the pattern vector is indicative of an impact of a proximity of the corresponding pixel on EMF excitation of the corresponding pixel.

30. The medium of clause 1, wherein the group of data points associated with each pattern of the set of patterns includes a group of pattern vectors, wherein each pattern vector corresponds to a pixel of a plurality of pixels of the corresponding pattern.

31. The medium of clause 1, wherein each pattern of the set of patterns is represented as a plurality of members in the representation domain, wherein each member corresponds to a pixel of the pattern.

32. A non-transitory computer-readable medium to represent patterns in a representation domain, the medium comprising instructions stored therein that, when executed by one or more processors, cause operations comprising:
obtaining a set of patterns, each pattern comprising one or more features; and
converting each pattern of the set of patterns into a group of data points in a representation domain, each data point indicative of information associated with features within a portion of a given pattern of the set of patterns.

33. The medium of clause 32, wherein representing each pattern as the group of data points in the representation domain comprises:
converting by a set of basis functions the given pattern, the set of basis functions characterizing the representation domain.

34. The medium of clause 33, wherein upon conversion, the group of data points are a set of coefficients associated with the set of basis functions.

35. The medium of clause 34, wherein the set of coefficients associated with the set of basis functions correspond to a set of locations of pixels of the given pattern in the representative domain.

36. The medium of clause 33, wherein the set of basis functions are a set of orthogonal functions.

37. The medium of any of clauses 33-36, wherein the converting comprises:
projecting the given pattern of the set of patterns in linear representation domain.

38. The medium of clause 37, wherein the projecting comprises: determining a linear combination of the set of orthogonal functions representing the given pattern of the set of patterns.

39. The medium of any of clauses 33-38, wherein the set of basis functions comprises at least one of:
Hermite Gaussian modes;
Zernike polynomials; or
Bessel functions.

40. The medium of any of clauses 32-39, wherein the representation domain is a Hilbert space domain.

41. A non-transitory computer-readable medium configured to select representative patterns for training machine learning models, the medium comprising instructions stored therein that, when executed by one or more processors, cause operations comprising:
obtaining a set of patterns;
representing each pattern of the set of patterns as a group of data points in a representation domain; and
selecting a subset of patterns from the set of patterns based on the groups of data points as a guide for mutual information between a given pattern and another pattern of the set of patterns.

42. The medium of clause 41, wherein each data point represents the information associated with features within a portion of the given pattern of the set of patterns.

43. The medium of clause 42, wherein the information associated with the features comprises pixel values within the portion of the given pattern

44. The medium of any of clauses 41-43, wherein the amount of mutual information between the given pattern and the other pattern indicates how much information in the given pattern is common with the other pattern, a high amount of mutual information indicates a high amount of common information between the given pattern and the other pattern.

45. The medium of any of clauses 41-44, wherein representing each pattern as the group of data points in the representation domain comprises:
converting by a set of basis functions the given pattern, the set of basis functions characterizing the representation domain.

46. The medium of clause 45, wherein upon conversion, the group of data points are a set of coefficients associated with the set of basis functions.

47. The medium of clause 46, wherein the set of coefficients associated with the set of basis functions correspond to a set of locations of pixels of the given pattern in the representative domain.

48. The medium of any of clauses 45-47, wherein the set of basis functions are a set of orthogonal functions.

49. The medium of any of clauses 45-48, wherein the converting comprises:
projecting the given pattern of the set of patterns in linear representation domain.

50. The medium of clause 49, wherein the projecting comprises: determining a linear combination of the set of orthogonal functions representing the given pattern of the set of patterns.

51. The medium of any of clauses 45-50, wherein the set of basis functions comprises at least one of:
Hermite Gaussian modes;
Zernike polynomials; or
Bessel functions.

52. The medium of any of clauses 41-51, wherein the representation domain is a Hilbert space domain.

53. The medium of any of clauses 41-52, wherein selecting the subset of patterns comprises selecting a plurality of patterns from the set of patterns based on a total entropy of the selected patterns.

54. The medium of clause 53, wherein selecting comprises:
determining the total entropy as a combination of information entropy associated with each group of data points corresponding to each pattern of the set of patterns.

55. The medium of clause 54, wherein selecting the subset of patterns from the set of patterns comprises:
selecting a plurality of groups from the groups representing the set of patterns, each selected group having a value of a distance metric breaching a distance threshold, the distance metric indicating a distance between the selected group and another of the groups representing the set of patterns; and
determining, for the selected groups, whether information entropy in the representation domain is maximized;
responsive to the information entropy not being maximized, adding other group to the selected plurality of groups or removing a group from the selected plurality of groups and repeating steps until the information entropy is maximized; and
selecting a plurality of patterns corresponding to the selected plurality of groups.

56. The medium of clause 55, wherein the distance metric comprises:
Kullback-Leibler divergence computed using the data points within a group in the representation domain; or
k-mean of nearest neighbors computed using the data points within a group in the representation domain.

57. The medium of any of clauses 41-56, wherein the set of patterns comprises patterns obtained from:
a design layout desired to be printed on a substrate;
a simulated image associated with a patterning process; or
an image associated with a patterned substrate.

58. The medium of any of clauses 41-57, wherein the simulated image comprises at least one of: an aerial image, a mask image, a resist image, or an etch image.

59. The medium of clause 58, wherein the image of the patterned substrate comprises a scanning electron microscope (SEM) image of the patterned substrate.

60. The medium of any of clauses 41-59, further comprising:
training, based on the subset of patterns, a machine learning model configured to determine characteristics of a patterning process.

61. The medium of clause 60, wherein the machine learning model is configured to determine characteristics of an illumination source of a lithography apparatus, a mask pattern of a mask, a projection system of the lithography apparatus, or a resist used for printing pattern on a substrate.

62. The medium of any of clauses 41-61, wherein representing each pattern as the data points in the representation domain does not include using a machine learning model.

63. A method for selecting patterns based on mutual information between the patterns for training machine learning models related to semiconductor manufacturing, the method comprising:
obtaining a set of patterns including a first pattern and a second pattern, each pattern of the set of patterns comprising one or more features;
representing each pattern of the set of patterns as a group of data points in a representation domain, the first pattern represented as a first group of data points in the representation domain, and the second pattern represented as a second group of data points in the representation domain, each data point of the first group being indicative of information associated with features within a portion of the first pattern, and each data point of the second group is indicative of information associated with features within a portion of the second pattern;
determining a set of distance values of a distance metric corresponding to the set of patterns, the set of distance values comprising a first distance value determined between the first group of data points and another group of data points, and the second distance value being determined between the second group of data points and the other group of data points, the distance metric being indicative of an amount of mutual information between a given pattern and the other pattern of the set of patterns; and
selecting, based on the values of the distance metric breaching a distance threshold, a subset of patterns from the set of patterns.

64. The method of clause 63, wherein the set of patterns comprises patterns obtained from:
a design layout desired to be printed on a substrate;
a simulated image associated with a patterning process; or
an image associated with a patterned substrate.

65. The method of clause 64, wherein the simulated image comprises at least one of: an aerial image, a mask image, a resist image, or an etch image.

66. The method of clause 64, wherein the image of the patterned substrate comprises a scanning electron microscope (SEM) image of the patterned substrate.

67. The method of any of clauses 63-66, wherein the information associated with features within a portion of the given pattern of the set of patterns comprises:
pixel values within the portion of the given pattern, the pixel values indicative of intensity associated with a feature within the portion.

68. The method of any of clauses 63-67, wherein the amount of mutual information between the given pattern and the other pattern indicates how much information in the given pattern is common with the other pattern, a high amount of mutual information indicates a high amount of common information between the given pattern and the other pattern.

69. The method of any of clauses 63-68, wherein representing each pattern as the group of data points in the representation domain comprises:
converting by a set of basis functions the given pattern, the set of basis functions characterizing the representation domain.

70. The method of clause 69, wherein upon conversion, each pixel of the given corresponds to a set of coefficients associated with the set of basis functions.

71. The method of clause 70, wherein the set of coefficients associated with the set of basis functions correspond to a set of TCCs.

72. The method of clause 70, wherein the set of basis functions includes a set of TCC functions.

73. The method of clause 69, wherein upon conversion, the group of data points are a set of coefficients associated with the set of basis functions.

74. The method of clause 73, wherein the set of coefficients associated with the set of basis functions correspond to a set of locations of pixels of the given pattern in the representative domain.

75. The method of any of clauses 69-74, wherein the set of basis functions are a set of orthogonal functions.

76. The method of any of clauses 69-75, wherein the converting comprises:
projecting the given pattern of the set of patterns in linear representation domain.

77. The method of clause 76, wherein the projecting comprises:
determining a linear combination of the set of orthogonal functions representing the given pattern of the set of patterns.

78. The method of any of clauses 69-74, wherein the set of basis functions comprises at least one of:
Hermite Gaussian modes;
Zernike polynomials; or
Bessel functions.

79. The method of any of clauses 63-78, wherein the representation domain is a Hilbert space domain.

80. The method of any of clauses 63-79, wherein selecting the subset of patterns comprises selecting a plurality of patterns from the set of patterns based on a total entropy of the selected patterns.

81. The method of clause 80, wherein selecting comprises:
determining the total entropy as a combination of information entropy associated with each group of data points corresponding to each pattern of the set of patterns.

82. The method of clause 81, wherein selecting the subset of patterns from the set of patterns comprises:
selecting a plurality of groups from the groups representing the set of patterns, each selected group having a value of the distance metric breaching the distance threshold; and
determining, for the selected groups, whether information entropy in the representation domain is maximized;
responsive to the information entropy not being maximized, adding other group to the selected plurality of groups or removing a group from the selected plurality of groups and repeating steps until the information entropy is maximized; and
selecting a plurality of patterns corresponding to the selected plurality of groups.

83. The method of any of clauses 63-82, wherein the distance metric comprises:
Kullback-Leibler divergence computed using the data points within a group in the representation domain; or
k-mean of nearest neighbors computed using the data points within a group in the representation domain.

84. The method of any of clauses 63-83, further comprising:
training, based on the subset of patterns, a machine learning model configured to determine characteristics of a patterning process.

85. The method of any of clauses 63-84, wherein the machine learning model is configured to determine characteristics of an illumination source of a lithography apparatus, a mask pattern of a mask, a projection system of the lithography apparatus, or a resist used for printing pattern on a substrate.

86. The method of any of clauses 63-85, wherein representing each pattern as the data points in the representation domain does not include using a machine learning model.

87. The method of clause 63, wherein the representation domain corresponds to electromagnetic functions.

88. The method of clause 87, wherein the electromagnetic functions are a set of transmission cross coefficient (TCC) functions associated with an illumination source of a lithographic apparatus that is used to print the first set of patterns on a substrate.

89. The method of clause 88, wherein representing each pattern includes:
representing a pixel of a pattern of the set of patterns as a pattern vector with each element in the pattern vector corresponding to a projection of the pixel at a TCC of the set of TCC functions.

90. The method of clause 89, wherein the pattern vector is indicative of an EMF excitation of the corresponding pixel.

91. The method of clause 89, wherein the pattern vector is indicative of an impact of a proximity of the corresponding pixel on EMF excitation of the corresponding pixel.

92. The method of clause 63, wherein the group of data points associated with each pattern of the set of patterns includes a group of pattern vectors, wherein each pattern vector corresponds to a pixel of a plurality of pixels of the corresponding pattern.

93. The method of clause 63, wherein each pattern of the set of patterns is represented as a plurality of members in the representation domain, wherein each member corresponds to a pixel of the pattern.

94. A method for representing patterns in a representation domain, the method comprising:
obtaining a set of patterns, each pattern comprising one or more features; and
converting each pattern of the set of patterns into a group of data points in a representation domain, each data point indicative of information associated with features within a portion of a given pattern of the set of patterns.

95. The method of clause 94, wherein representing each pattern as the group of data points in the representation domain comprises:
converting by a set of basis functions the given pattern, the set of basis functions characterizing the representation domain.

96. The method of clause 95, wherein upon conversion, the group of data points are a set of coefficients associated with the set of basis functions.

97. The method of clause 96, wherein the set of coefficients associated with the set of basis functions correspond to a set of locations of pixels of the given pattern in the representative domain.

98. The method of clause 95, wherein the set of basis functions are a set of orthogonal functions.

99. The method of any of clauses 95-98, wherein the converting comprises:
projecting the given pattern of the set of patterns in linear representation domain.

100. The method of clause 99, wherein the projecting comprises: determining a linear combination of the set of orthogonal functions representing the given pattern of the set of patterns.

101. The method of any of clauses 95-100, wherein the set of basis functions comprises at least one of:
Hermite Gaussian modes;
Zernike polynomials; or
Bessel functions.

102. The method of any of clauses 94-101, wherein the representation domain is a Hilbert space domain.

103. A method for selecting representative patterns for training machine learning models, the method comprising:
obtaining a set of patterns;
representing each pattern of the set of patterns as a group of data points in a representation domain; and
selecting a subset of patterns from the set of patterns based on the groups of data points as a guide for mutual information between a given pattern and another pattern of the set of patterns.

104. The method of clause 103, wherein each data point represents the information associated with features within a portion of the given pattern of the set of patterns.

105. The method of clause 104, wherein the information associated with the features comprises pixel values within the portion of the given pattern

106. The method of any of clauses 103-105, wherein the amount of mutual information between the given pattern and the other pattern indicates how much information in the given pattern is common with the other pattern, a high amount of mutual information indicates a high amount of common information between the given pattern and the other pattern.

107. The method of any of clauses 103-106, wherein representing each pattern as the group of data points in the representation domain comprises:
converting by a set of basis functions the given pattern, the set of basis functions characterizing the representation domain.

108. The method of clause 107, wherein upon conversion, the group of data points are a set of coefficients associated with the set of basis functions.

109. The method of clause 108, wherein the set of coefficients associated with the set of basis functions correspond to a set of locations of pixels of the given pattern in the representative domain.

110. The method of any of clauses 107-109, wherein the set of basis functions are a set of orthogonal functions.

111. The method of any of clauses 107-110, wherein the converting comprises:
projecting the given pattern of the set of patterns in linear representation domain.

112. The method of clause 111, wherein the projecting comprises: determining a linear combination of the set of orthogonal functions representing the given pattern of the set of patterns.

113. The method of any of clauses 107-112, wherein the set of basis functions comprises at least one of:
Hermite Gaussian modes;
Zernike polynomials; or
Bessel functions.

114. The method of any of clauses 103-113, wherein the representation domain is a Hilbert space domain.

115. The method of any of clauses 103-114, wherein selecting the subset of patterns comprises selecting a plurality of patterns from the set of patterns based on a total entropy of the selected patterns.

116. The method of clause 115, wherein selecting comprises:
determining the total entropy as a combination of information entropy associated with each group of data points corresponding to each pattern of the set of patterns.

117. The method of clause 116, wherein selecting the subset of patterns from the set of patterns comprises:
selecting a plurality of groups from the groups representing the set of patterns, each selected group having a value of a distance metric breaching a distance threshold, the distance metric indicating a distance between the selected group and another of the groups representing the set of patterns; and
determining, for the selected groups, whether information entropy in the representation domain is maximized;
responsive to the information entropy not being maximized, adding other group to the selected plurality of groups or removing a group from the selected plurality of groups and repeating steps until the information entropy is maximized; and
selecting a plurality of patterns corresponding to the selected plurality of groups.

118. The method of clause 117, wherein the distance metric comprises:
Kullback-Leibler divergence computed using the data points within a group in the representation domain; or
k-mean of nearest neighbors computed using the data points within a group in the representation domain.

119. The method of any of clauses 103-118, wherein the set of patterns comprises patterns obtained from:
a design layout desired to be printed on a substrate;
a simulated image associated with a patterning process; or
an image associated with a patterned substrate.

120. The method of any of clauses 103-119, wherein the simulated image comprises at least one of: an aerial image, a mask image, a resist image, or an etch image.

121. The method of clause 120, wherein the image of the patterned substrate comprises a scanning electron microscope (SEM) image of the patterned substrate.

122. The method of any of clauses 103-121, further comprising:
training, based on the subset of patterns, a machine learning model configured to determine characteristics of a patterning process.

123. The method of clause 122, wherein the machine learning model is configured to determine characteristics of an illumination source of a lithography apparatus, a mask pattern of a mask, a projection system of the lithography apparatus, or a resist used for printing pattern on a substrate.

124. The method of any of clauses 103-123, wherein representing each pattern as the data points in the representation domain does not include using a machine learning model.

125. A non-transitory computer-readable medium having instructions that, when executed by a computer, cause the computer to execute a method for pattern selection for training or calibrating models related to semiconductor manufacturing, the method comprising:
obtaining a first set of patterns;
representing each pattern of the first set of patterns in a representation domain, the representation domain corresponding to electromagnetic functions; and
selecting a second set of patterns from the first set of patterns based on the representation domain.

126. The computer-readable medium of clause 125, wherein the electromagnetic functions are a set of transmission cross coefficient (TCC) functions associated with an illumination source of a lithographic apparatus that is used to print the first set of patterns on a substrate.

127. The computer-readable medium of clause 126, wherein representing each pattern includes:
representing a pixel of a pattern of the first set of patterns as a pattern vector with each element in the pattern vector corresponding to a projection of the pixel at a TCC of the set of TCC functions.

128. The computer-readable medium of clause 127, wherein the pattern vector is indicative of an EMF excitation of the corresponding pixel.

129. The computer-readable medium of clause 127, wherein the pattern vector is indicative of an impact of a proximity of the corresponding pixel on EMF excitation of the corresponding pixel.

130. The computer-readable medium of clause 125, wherein each pattern of the first set of patterns is represented as a group of pattern vectors, wherein each pattern vector corresponds to a pixel of a plurality of pixels of the corresponding pattern.

131. The computer-readable medium of clause 125, wherein each pattern of the first set of patterns is represented as a plurality of members in the representation domain, wherein each member corresponds to a pixel of the pattern.

132. The computer-readable medium of clause 125, wherein selecting the second set of patterns includes selecting a plurality of patterns from the first set of patterns based on a total entropy of the second set of patterns.

133. The computer-readable medium of clause 132, wherein selecting the second set of patterns includes:
determining the total entropy as a combination of information entropy associated with each group of pattern vectors corresponding to each pattern of the first set of patterns.

134. The computer-readable medium of clause 133, wherein selecting the second set of patterns from the first set of patterns includes:
selecting a plurality of groups from the groups representing the set of patterns, each selected group having a value of a distance metric satisfying a distance threshold;
determining, for the plurality of groups, whether information entropy of the representation domain meet a prescribed criteria;
responsive to the information entropy not meeting the prescribed criteria, adding other group to the plurality of groups or removing a group from the plurality of groups and repeating steps; and
selecting a plurality of patterns corresponding to the plurality of groups.

135. The computer-readable medium of clause 134, wherein the distance metric includes:
Kullback-Leibler divergence computed using pattern vectors within a group in the representation domain; or
k-mean of nearest neighbors computed using pattern vectors within a group in the representation domain.

136. The computer-readable medium of clause 125, the method further comprising:
training, based on the second set of patterns, a machine learning model configured to determine characteristics of a patterning process.

137. The computer-readable medium of clause 136, wherein the machine learning model is configured to determine characteristics of at least one of an illumination source of a lithography apparatus, a mask pattern of a mask, a projection system of the lithography apparatus, or a resist used for printing pattern on a substrate.

138. The computer-readable medium of clause 125, wherein representing each pattern in the representation domain includes:
converting a given pattern of the first set of patterns by a set of basis functions characterizing the representation domain.

139. The computer-readable medium of clause 138, wherein upon conversion, each pixel of the given pattern corresponds to a set of coefficients associated with the set of basis functions.

140. The computer-readable medium of clause 139, wherein the set of coefficients associated with the set of basis functions correspond to a set of TCCs.

141. The computer-readable medium of 138, wherein the set of basis functions is a set of orthogonal functions.

142. The computer-readable medium of clause 138, wherein converting the given pattern includes: projecting the given pattern in a linear representation domain.

143. The computer-readable medium of clause 138, wherein the set of basis functions includes a set of TCC functions.

144. The computer-readable medium of clause 125, wherein the representation domain is a Hilbert space domain.

145. A method for pattern selection for training or calibrating models related to semiconductor manufacturing, the method comprising:
obtaining a first set of patterns;
representing each pattern of the first set of patterns in a representation domain, the representation domain corresponding to electromagnetic functions; and
selecting a second set of patterns from the first set of patterns based on the representation domain.

146. The method of clause 145, wherein the electromagnetic functions are a set of transmission cross coefficient (TCC) functions associated with an illumination source of a lithographic apparatus that is used to print the first set of patterns on a substrate.

147. The method of clause 146, wherein representing each pattern includes:
representing a pixel of a pattern of the first set of patterns as a pattern vector with each element in the pattern vector corresponding to a projection of the pixel at a TCC of the set of TCC functions.

148. The method of clause 147, wherein the pattern vector is indicative of an EMF excitation of the corresponding pixel.

149. The method of clause 147, wherein the pattern vector is indicative of an impact of a proximity of the corresponding pixel on EMF excitation of the corresponding pixel.

150. The method of clause 145, wherein each pattern of the first set of patterns is represented as a group of pattern vectors, wherein each pattern vector corresponds to a pixel of a plurality of pixels of the corresponding pattern.

151. The method of clause 145, wherein each pattern of the first set of patterns is represented as a plurality of members in the representation domain, wherein each member corresponds to a pixel of the pattern.

152. The method of clause 145, wherein selecting the second set of patterns includes selecting a plurality of patterns from the first set of patterns based on a total entropy of the second set of patterns.

153. The method of clause 152, wherein selecting the second set of patterns includes: determining the total entropy as a combination of information entropy associated with each group of pattern vectors corresponding to each pattern of the first set of patterns.

154. The method of clause 153, wherein selecting the second set of patterns from the first set of patterns includes:
selecting a plurality of groups from the groups representing the set of patterns, each selected group having a value of a distance metric satisfying a distance threshold;
determining, for the plurality of groups, whether information entropy of the representation domain meet a prescribed criteria;
responsive to the information entropy not meeting the prescribed criteria, adding other group to the plurality of groups or removing a group from the plurality of groups and repeating steps; and
selecting a plurality of patterns corresponding to the plurality of groups.

155. The method of clause 154, wherein the distance metric includes:
Kullback-Leibler divergence computed using pattern vectors within a group in the representation domain; or
k-mean of nearest neighbors computed using pattern vectors within a group in the representation domain.

156. The method of clause 145, further comprising:
training, based on the second set of patterns, a machine learning model configured to determine characteristics of a patterning process.

157. The method of clause 156, wherein the machine learning model is configured to determine characteristics of at least one of an illumination source of a lithography apparatus, a mask pattern of a mask, a projection system of the lithography apparatus, or a resist used for printing pattern on a substrate.

158. The method of clause 145, wherein representing each pattern in the representation domain includes:
converting a given pattern of the first set of patterns by a set of basis functions characterizing the representation domain.

159. The method of clause 158, wherein upon conversion, each pixel of the given pattern corresponds to a set of coefficients associated with the set of basis functions.

160. The method of clause 159, wherein the set of coefficients associated with the set of basis functions correspond to a set of TCCs.

161. The method of 158, wherein the set of basis functions is a set of orthogonal functions.

162. The method of clause 158, wherein converting the given pattern includes:
projecting the given pattern in a linear representation domain.

163. The method of clause 158, wherein the set of basis functions includes a set of TCC functions.

164. The method of clause 145, wherein the representation domain is a Hilbert space domain.

While the concepts disclosed herein may be used for imaging on a substrate such as a silicon wafer, it shall be understood that the disclosed concepts may be used with any type of lithographic imaging systems, e.g., those used for imaging on substrates other than silicon wafers. The descriptions herein are intended to be illustrative, not limiting. Thus, it will be apparent to one skilled in the art that modifications may be made as described without departing from the scope of the claims set out below.

1. A method of pattern selection for a semiconductor manufacturing related process, the method comprising:
obtaining a set of patterns;
representing each pattern of the set of patterns as a group of data points in a representation domain, wherein each data point represents the information associated with features within a portion of the given pattern of the set of patterns and wherein the representing comprises converting the given pattern using a set of basis functions, the set of basis functions characterizing the representation domain; and
selecting a subset of patterns from the set of patterns based on the groups of data points as a guide for mutual information between a given pattern and another pattern of the set of patterns.

2. The method of claim 1, wherein the information associated with the features comprises pixel values within the portion of the given pattern.

3. The method of claim 1, wherein the amount of mutual information between the given pattern and the other pattern indicates an amount of information in the given pattern that is common with the other pattern.

4. (canceled)

5. The method of claim 1, wherein upon conversion, the group of data points corresponds to a set of coefficients associated with the set of basis functions.

6.-12. (canceled)

13. The method of claim 1, wherein the representation domain corresponds to electromagnetic functions.

14. (canceled)

15. A non-transitory computer-readable medium having instructions that, when executed by a computer system, are configured to cause the computer system to at least:
obtain a set of patterns;
represent each pattern of the set of patterns as a group of data points in a representation domain, wherein each data point represents the information associated with features within a portion of the given pattern of the set of patterns, and wherein the representation of each pattern comprises conversion of the given pattern using a set of basis functions, the set of basis functions characterizing the representation domain; and
select a subset of patterns for a semiconductor manufacturing related process from the set of patterns based on the groups of data points as a guide for mutual information between a given pattern and another pattern of the set of patterns.

16. The medium of claim 15, wherein the information associated with the features comprises pixel values within the portion of the given pattern.

17. The medium of claim 15, wherein the amount of mutual information between the given pattern and the other pattern indicates an amount of information in the given pattern that is common with the other pattern.

18. The medium of claim 15, wherein the set of patterns comprises patterns obtained from: a design layout desired to be printed on a substrate; a simulated image associated with a patterning process; or a measured image associated with a patterned substrate.

19. The medium of claim 15, wherein upon conversion, the group of data points corresponds to a set of coefficients associated with the set of basis functions.

20. The medium of claim 19, wherein the set of coefficients associated with the set of basis functions correspond to a set of locations of pixels of the given pattern in the representative domain.

21. The medium of claim 15, wherein the instructions configured to cause the computer to convert the given pattern are further configured to cause the computer system to:
project the given pattern of the set of patterns in a linear representation domain, and
determine a linear combination of a set of orthogonal functions representing the given pattern of the set of patterns.

22. The medium of claim 15, wherein the set of basis functions comprises at least one selected from:
a Hermite Gaussian mode;
a Zernike polynomial; or
a Bessel function.

23. The medium of claim 15, wherein the representation domain is a Hilbert space domain.

24. The medium of claim 15, wherein the instructions configured to cause the computer system to select the subset of patterns are further configured to cause the computer system to determine a total entropy of the selected patterns as a combination of information entropy associated with each group of data points corresponding to each pattern of the set of patterns, and select a plurality of patterns from the set of patterns based on the total entropy of the selected patterns.

25. The medium of claim 24, wherein the instructions configured to cause the computer system to select the subset of patterns from the set of patterns are further configured to cause the computer system to:
i) select a plurality of groups from the groups representing the set of patterns, each selected group having a value of a distance metric breaching a distance threshold, the distance metric indicating a distance between the selected group and another of the groups representing the set of patterns;
ii) determine, for the selected groups, whether information entropy in the representation domain is maximized;
iii) responsive to the information entropy not being maximized, add another group to the selected plurality of groups or remove a group from the selected plurality of groups;
iv) repeat i)-iii) until the information entropy is maximized; and
v) select a plurality of patterns corresponding to the selected plurality of groups.

26. The medium of claim 15, wherein the instruction are further configured to cause the computer system to:
train, based on the subset of patterns, a machine learning model configured to determine one or more characteristics of a patterning process;
calibrate a non-machine learning model using the subset of patterns; or
cause performance of metrology or inspection measurement on the subset of patterns.

27. The medium of claim 15, wherein the set of basis functions corresponds to electromagnetic functions.

28. The medium of claim 27, wherein the electromagnetic functions comprise a set of transmission cross coefficient (TCC) functions associated with an illumination of a lithographic apparatus that is used to print one or more patterns of the set of patterns on a substrate.

29. The medium of claim 15, wherein the instruction are further configured to cause the computer system to train, based on the subset of patterns, a machine learning model configured to determine one or more characteristics of a patterning process, wherein the machine learning model is configured to determine one or more characteristics of: an illumination of a lithography apparatus, a mask pattern of a mask, a projection system of the lithography apparatus, or a resist used for printing a pattern on a substrate.
